(19) United States
(12) Patent Application Publication
(10) Pub. No.: US 2026/0114130 A1
(43) Pub. Date: Apr. 23, 2026

(54) DISPLAY DEVICE

(71) Applicant: LG Display Co., Ltd., Seoul (KR)

(72) Inventors: Seongjoo Lee, Goyang-si (KR); JungSun Baek, Paju-si (KR); Yongmin Kim, Anyang-si (KR)

(73) Assignee: LG Display Co., Ltd., Seoul (KR)

(21) Appl. No.: 19/312,672

(22) Filed: Aug. 28, 2025

(30) Foreign Application Priority Data
Oct. 18, 2024 (KR) 10-2024-0143236

(51) Int. Cl. H10K 59/122

(52) U.S. Cl. CPC H10K 59/122

(57) ABSTRACT

A display device according to one or more examples includes a substrate, a plurality of sub pixels, a planarization layer disposed above the substrate and has a first open area, an anode disposed in the first open area and on a top surface and a side portion of the planarization layer, a first bank covering a part of the anode and including a black resin, a second bank covering the first bank and a side portion of the anode and having a second open area, an organic layer disposed on the anode exposed by the second open area, and a cathode disposed on the organic layer and improves the reflectance.

### CROSS-REFERENCE TO RELATED APPLICATIONS

This application claims the benefit of and priority to Korean Patent Application No. 10-2024-0143236 filed on Oct. 18, 2024, in the Korean Intellectual Property Office, the entire contents of which are incorporated herein by reference for all purposes.

### BACKGROUND

### 1. Technical Field

The present disclosure relates to a display device.

### 2. Description of Related Art

Currently, as it enters a full-scale information era, a field of a display device which visually expresses electrical information signals has been rapidly developed and studies are continued to improve performances of various display devices such as a thin-thickness, a light weight, and low power consumption.

Among various display devices, an electroluminescent display device is a self-emitting display device so that a separate light source is not necessary, which is different from a liquid crystal display device. Therefore, the light emitting display device may be manufactured to have a light weight and a small thickness. Further, since the electroluminescent display device is driven at a low voltage so that it is advantageous not only in terms of power consumption, but also in terms of color implementation, a response speed, a viewing angle, a contrast ratio. Therefore, it is expected to be utilized in various fields.

In the meantime, light emitted from an emission layer of the electroluminescent display device passes through various components of the electroluminescent display device to be released to the outside of the electroluminescent display device. However, when some of light emitted from the emission layer is trapped in the electroluminescent display device without being released to the outside of the electroluminescent display device, the light extraction efficiency of the electroluminescent display device may be degraded.

The description of related art should not be considered prior art merely because it is mentioned in or associated with this section. The description of related art includes information that describes one or more aspects of the subject technology, and the description in this section does not limit the scope of the invention.

### SUMMARY

An aspect to be achieved by the present disclosure is to provide a display device which improves an amount of extracted light.

Another aspect to be achieved by the present disclosure is to provide a display device with a display panel with a reduced thickness.

Still another aspect to be achieved by the present disclosure is to provide a display device which reduces a power consumption.

Still another aspect to be achieved by the present disclosure is to provide a display device with improved reflective visibility.

Aspects of the present disclosure are not limited to the above-mentioned aspects, and other aspects, which are not mentioned above, can be clearly understood by those skilled in the art from the present disclosure.

In order to achieve the aspects as described above, according to an aspect of the present disclosure, a display device includes a substrate, a plurality of sub pixels, a planarization layer disposed above the substrate and having a first open area, an anode disposed in the first open area and on a top surface and a side portion of the planarization layer, a first bank covering a part of the anode and comprising black resin, a second bank covering the first bank and a side portion of the anode and having a second open area, an organic layer disposed on the anode exposed by the second open area, and a cathode disposed on the organic layer.

Other detailed matters of the example embodiments are included in the detailed description and the drawings.

According to one or more aspects of the present disclosure, an amount of extracted light of a display device may be increased using a side mirror (SM) structure of an anode. Therefore, the display device can operate with reduced power consumption. Further, it is possible to implement ESG (Environment/Social/Governance) by reducing greenhouse gas emissions by reducing the use of fossil fuels for power generation.

According to one or more aspects of the present disclosure, a color on encapsulation (COE) structure is used to reduce the thickness of the display panel. Accordingly, a lightweight and slim design can be achieved.

According to one or more aspects of the present disclosure, a black bank is provided on the anode with an SM structure to improve the reflectance. Therefore, light entering the thin film transistor (TFT) element is blocked, enhancing device reliability.

According to one or more aspects of the present disclosure, a display device may be provided in which a light receiving device is located behind the display panel so that the light receiving device which needs to receive light from the front surface is not exposed to the front surface. Therefore, a bezel of the front surface of the display device is reduced, and a front surface design of the display device may be enhanced.

According to one or more aspects of the present disclosure, when a light receiving device is located behind the display panel, a transmission area is additionally ensured in the first active area which overlaps the light receiving device to satisfactorily transmit light from the front surface of the display panel to the light receiving device through the display panel. Therefore, an image quality of the light receiving device may be improved.

The effects according to one or more aspects of the present disclosure are not limited to the contents provided above, and various other effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is an example view schematically illustrating a configuration of a display device according to example embodiments of the present disclosure;

FIG. 2 is an example plan view schematically illustrating a display panel of FIG. 1;

FIG. 3 is an example perspective view illustrating a structure in which a touch panel is embedded in a display panel;

FIG. 4 is an example view illustrating a pixel structure of a display panel according to a first example embodiment of the present disclosure;

FIG. 5 is an example cross-sectional view taken along the line A-A′ of FIG. 4;

FIG. 6 is an example cross-sectional view illustrating a sub pixel structure of a second example embodiment of the present disclosure;

FIG. 7 is an example view illustrating an emission image taken along the cross-section of FIG. 6;

FIG. 8 is an example plan view schematically illustrating a display device according to a third example embodiment of the present disclosure;

FIG. 9 is an example view illustrating a first active area of a display device of FIG. 8;

FIG. 10 is an example view illustrating a part A of FIG. 8;

FIG. 11 is an example view illustrating a cross-sectional structure of a non-transmission area and a transmission area in a first active area and a cross-sectional structure of a second active area, in a display device according to a third example embodiment of the present disclosure;

FIG. 12 is an example cross-sectional view illustrating a sub pixel structure of a third example embodiment of the present disclosure;

FIG. 13 is an example view illustrating a pixel structure of a display panel according to a fourth example embodiment of the present disclosure;

FIG. 14 is an example cross-sectional view taken along the line B-B′ of FIG. 13;

FIG. 15 is an example cross-sectional view illustrating a sub pixel structure of a fifth example embodiment of the present disclosure;

FIG. 16 is an example view illustrating a pixel structure of a display panel according to a sixth example embodiment of the present disclosure; and

FIG. 17 is an example cross-sectional view taken along the line C-C′ of FIG. 16.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,”“on,”“below”and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),”is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element. Further, “some,” “some portions,” “some parts,” “a portion,” “one or more portions,” “a part,” “one or more parts,” or the like may refer to “at least some,” “at least some portions,” “at least some parts,” “at least a portion,” “at least one or more portions,” “at least a part,” “at least one or more parts,” or the like, respectively.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” or “unit” may apply, for example, to a separate circuit, component or structure, an integrated circuit, a computational block of a circuit device, or a structure configured to perform a described function as should be understood by one of ordinary skill in the art.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like elements unless stated otherwise. The same or similar elements may be denoted by the same reference numerals even though they are depicted in different drawings. Repetitive descriptions of the same or similar elements may be omitted for brevity, and the descriptions provided for elements in one or more figures may also apply to elements in other figures that use the same reference numerals unless stated otherwise.

For the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

Hereinafter, example embodiments of the present disclosure will be described in detail with reference to the drawings.

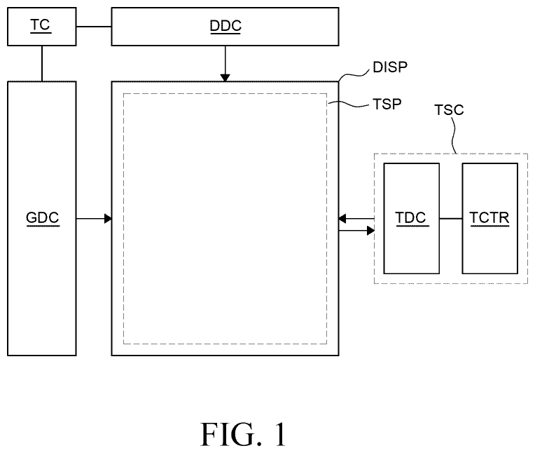

FIG. 1 is an example view schematically illustrating a configuration of a display device according to example embodiments of the present disclosure.

For example, FIG. 1 illustrates a schematic configuration of a display device in which a touch panel TSP according to example embodiments of the present disclosure is embedded. However, the present disclosure is not limited thereto and a display device according to the example embodiments of the present disclosure may not include a display panel.

Referring to FIG. 1, the display device according to example embodiments of the present disclosure may provide both a function for displaying images and a function for sensing a touch.

In order to provide an image displaying function, the display device according to the example embodiments of the present disclosure may include a display panel DISP, a gate driving circuit GDC, a data driving circuit DDC, and a timing controller TC.

For example, in the display panel DISP, a plurality of data lines and a plurality of gate lines are disposed and a plurality of sub pixels defined by the plurality of data lines and the plurality of gate lines may be disposed.

The data driving circuit DDC drives a plurality of data lines and the gate driving circuit GDC drives a plurality of gate lines, and the timing controller TC may control an operation of the data driving circuit DDC and the gate driving circuit GDC.

Each of the data driving circuit DDC, the gate driving circuit GDC, and the timing controller TC may be implemented by one or more individual components. In some cases, two or more of the data driving circuit DDC, the gate driving circuit GDC, and the timing controller TC may be implemented to be integrated as one component. For example, the data driving circuit DDC and the timing controller TC may be implemented as one integrated chip (IC chip).

Further, in order to provide a touch sensing function, the display device according to example embodiments of the present disclosure may include a touch panel TSP and a touch sensing circuit TSC. The touch panel TSP includes a plurality of touch electrodes. The touch sensing circuit TSC supplies a touch driving signal to the touch panel TSP and detects a touch sensing signal from the touch panel TSP to sense the presence of a touch of a user or a touch position (touch coordinate) in the touch panel TSP based on the detected touch sensing signal.

For example, the touch sensing circuit TSC may include a touch driving circuit TDC and a touch controller TCTR. The touch driving circuit TDC supplies a touch driving signal to the touch panel TSP and detects a touch sensing signal from the touch panel TSP. The touch controller TCTR senses the presence of a touch of a user and/or a touch position in the touch panel TSP based on the touch sensing signal detected by the touch driving circuit TDC. The touch driving circuit TDC may include a first circuit part which supplies the touch driving signal to the touch panel TSP and a second circuit part which detects the touch sensing signal from the touch panel TSP.

For example, the touch driving circuit TDC and the touch controller TCTR may be implemented by separate components or in some cases, may be implemented to be integrated as one component.

For example, each of the data driving circuit DDC, the gate driving circuit GDC, and the touch driving circuit TDC may be implemented by one or more integrated circuits. From the viewpoint of electrical connection with the display panel DISP, the circuits may be implemented by a chip on glass (COG) type, a chip on film (COF) type, or a tape carrier package (TCP) type. Further, the gate driving circuit GDC may also be implemented by a gate in panel (GIP) type.

For example, each of circuit configurations DDC, GDC, and TC for display driving and circuit configurations TDC and TCTR for touch sensing may be implemented by one or more individual components. In some cases, one or more of circuit configurations DDC, GDC, and TC for display driving and one or more of circuit configurations TDC and TCTR for touch sensing are functionally integrated to be implemented by one or more components.

For example, the data driving circuit DDC and the touch driving circuit TDC may be implemented to be integrated in one or two or more integrated circuit chips. When the data driving circuit DDC and the touch driving circuit TDC are implemented to be integrated in two or more integrated circuit chips, each of two or more integrated circuit chips may have a data driving function and a touch driving function.

In the meantime, the display device according to the example embodiments of the present disclosure may be various types such as a light emitting display device or a liquid crystal display device. Hereinafter, for the convenience of description, a light emitting display device will be described as an example of the display device. That is, even though the display panel DISP may be various types such as a light emitting display panel or a liquid crystal display panel, in the following description, for the convenience of description, a light emitting display panel will be described as an example of the display panel DISP.

Further, as it will be described below, the touch panel TSP may include a plurality of touch electrodes which is applied with a touch driving signal or detects a touch sensing signal and a plurality of touch routing lines which connects the plurality of touch electrodes to the touch driving circuit TDC.

The touch panel TSP may be provided at the outside of the display panel DISP. For example, the touch panel TSP and the display panel DISP may be separately manufactured to be combined. Such a touch panel TSP is called an external type or an add-on type.

In contrast, the touch panel TSP may be embedded in the display panel DISP. For example, when the display panel DISP is manufactured, a touch sensor structure such as a plurality of touch electrodes and a plurality of touch routing lines which configure the touch panel TSP may be formed together with a plurality of electrodes and signal lines for display driving.

Further, the touch panel TSP may be formed directly above an encapsulation unit of the display panel DISP. For example, the touch insulating film and the touch electrodes are patterned above the encapsulation unit and are connected to signal lines formed as electrodes for display driving to be driven. Hereinafter, for the convenience of description, an example that the touch panel TSP is formed directly above the encapsulation unit will be described.

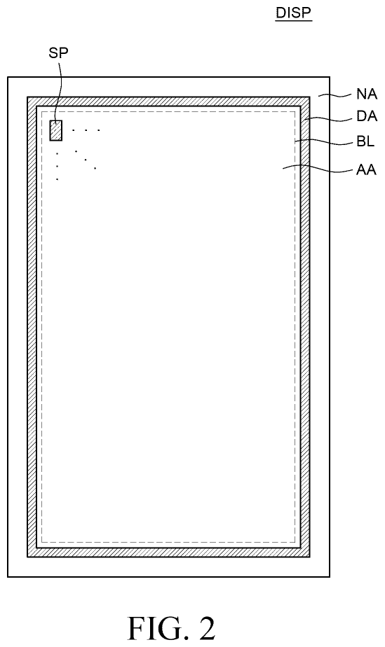

FIG. 2 is an example plan view schematically illustrating a display panel of FIG. 1.

Referring to FIG. 2, the display panel DISP may include an active area AA in which images are displayed and a non-active area NA which is an outer area of an outer boundary line BL of the active area AA.

In the active area AA of the display panel DISP, a plurality of sub pixels SP for displaying images is disposed and various electrodes or signal lines for display driving are disposed.

Further, in the active area AA of the display panel DISP, a plurality of touch electrodes for touch sensing and a plurality of touch routing lines electrically connected thereto may be disposed. Accordingly, the active area AA may also be referred to as a touch sensing area which is capable of sensing the touch.

In the non-active area NA of the display panel DISP, link lines extending from various signal lines disposed in the active area AA or link lines which are electrically connected to various signal lines disposed in the active area AA, and pads which are electrically connected to the link lines may be disposed. The pads disposed in the non-active area NA may be bonded or electrically connected with the display driving circuit.

Further, in the non-active area NA of the display panel DISP, link lines extending from a plurality of touch routing lines disposed in the active area AA or link lines which are electrically connected to a plurality of touch routing lines disposed in the active area AA, and pads which are electrically connected to the link lines may be disposed. The pads disposed in the non-active area NA may be bonded or electrically connected with the touch driving circuit.

In the non-active area NA, a part of an outermost touch electrode, among a plurality of touch electrodes disposed in the active area AA, extends or one or more electrodes (touch electrodes) formed of the same material as the plurality of touch electrodes disposed in the active area AA may be further disposed.

For example, all the plurality of touch electrodes disposed in the display panel DISP may be present in the active area AA or some (for example, an outermost touch electrode) among the plurality of touch electrodes disposed in the display panel DISP may be present in the non-active area NA. Some (for example, an outermost touch electrode) among the plurality of touch electrodes disposed in the display panel DISP may be present over the active area AA and the non-active area NA.

Referring to FIG. 2, the display panel DISP according to the example embodiments of the present disclosure may include a dam area DA having a dam for suppressing any layer (for example, the encapsulation unit in the display panel) in the active area AA from passing over the display panel DISP.

The dam area DA may be located at a boundary of the active area AA and the non-active area NA or at any one position of a non-active area NA which is an outer area of the active area AA.

A dam disposed in the dam area DA may be disposed to enclose all directions of the active area AA or disposed only at an outside of one or two or more parts of the active area AA.

The dam disposed in the dam area DA may have one pattern which is connected or two or more separated patterns. Further, in the dam area DA, only a primary dam may be disposed or two or more dams (primary dam and secondary dam) may be disposed, or three or more dams may also be disposed.

For example, in the dam area DA, in any one direction, only the primary dam is disposed and in the other direction, both the primary dam and the secondary dam may be disposed.

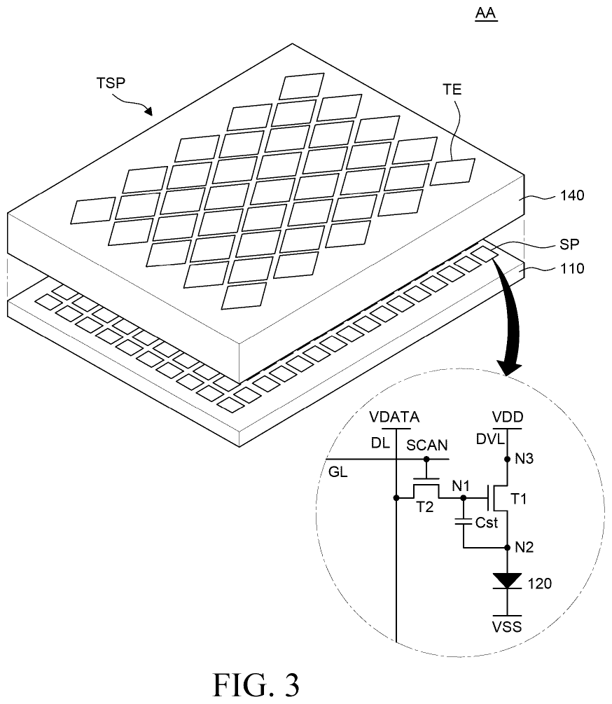

FIG. 3 is an example perspective view illustrating a structure in which a touch panel is embedded in a display panel.

FIG. 3 is an example perspective view illustrating a structure in which a touch panel is embedded in a display panel according to an example embodiments of the present disclosure.

Referring to FIG. 3, for example, in the active area AA of the display panel (DISP in FIG. 2), a plurality of sub pixels SP may be disposed above the substrate 110.

Each sub pixel SP may include a light emitting diode 120, a first transistor T1 for driving the light emitting diode 120, a second transistor T2 for transmitting a data voltage VDATA to a first node N1 of the first transistor T1, and a storage capacitor Cst for maintaining a constant voltage for one frame.

For example, the first transistor T1 may include a first node N1 to which the data voltage VDATA is applied, a second node N2 which is electrically connected to the light emitting diode 120, and a third node N3 to which a driving voltage VDD is applied from a driving voltage line DVL. The first node N1 is a gate node, the second node N2 may be a source node or a drain node, and the third node N3 may be a drain node or a source node. The first transistor T1 may also be referred to as a driving transistor which drives the light emitting diode 120.

The light emitting diode 120 may include a first electrode (for example, an anode), an emission layer, and a second electrode (for example, a cathode). The first electrode is electrically connected to the second node N2 of the first transistor T1 and the second electrode may be applied with a base voltage VSS.

The emission layer in the light emitting diode 120 may be configured by an organic material or an inorganic material.

For example, the second transistor T2 is controlled to be turned on or off by a scan signal SCAN applied through the gate line GL and may be electrically connected between the first node N1 of the first transistor T1 and the data line DL. Further, the second transistor T2 may be referred to as a switching transistor.

For example, when the second transistor T2 is turned on by the scan signal SCAN, the second transistor T2 may transmit the data voltage VDATA supplied from the data line DL to the first node N1 of the first transistor T1.

Further, the storage capacitor Cst may be electrically connected between the first node N1 and the second node N2 of the first transistor T1.

As illustrated in FIG. 3, each sub pixel SP may have a 2T1C structure including two transistors T1 and T2 and one capacitor Cst and in some cases, may further include one or more transistors or further include one or more capacitors.

The first transistor T1 and the second transistor T2 may be configured by an n-type transistor or a p-type transistor. As described above, in the display panel DISP, circuit elements such as a light emitting diode 120, two or more transistors T1 and T2, and one or more capacitors Cst may be disposed. The circuit element (specifically, the light emitting diode 120) is vulnerable to external moisture or oxygen so that an encapsulation unit 140 for suppressing the external moisture or oxygen from permeating the circuit element may be disposed on the display panel DISP.

The encapsulation unit 140 may be formed by one layer, or also formed by a plurality of layers.

In the meantime, in the display device according to the example embodiments of the present disclosure, the touch panel TSP may be disposed above the encapsulation unit 140. For example, in the display device according to the example embodiments of the present disclosure, a touch sensor structure, such as a plurality of touch electrodes TE which configures a touch panel TSP, may be disposed above the encapsulation unit 140.

Further, the display device according to the example embodiments of the present disclosure may sense the touch based on capacitance formed in the touch electrode TE.

The display device according to the example embodiments of the present disclosure employs a capacitance based touch sensing manner so that the touch is sensed by a mutual-capacitance based touch sensing manner or a self-capacitance based touch sensing manner.

For example, according to the mutual-capacitance based touch sensing manner, a plurality of touch electrodes TE may be classified into a driving touch electrode (a transmission touch electrode) to which a touch driving signal is applied and a sensing touch electrode (a reception touch electrode) which detects a touch sensing signal and forms a capacitance with the driving touch electrode.

In the case of the mutual-capacitance based touch sensing manner, the touch sensing circuit may sense the presence of the touch and/or the touch coordinate based on the change in capacitance (mutual-capacitance) between the driving touch electrode and the sensing touch electrode depending on the presence of a pointer such as a finger or a pen.

According to the self-capacitance based touch sensing manner, each touch electrode TE may serve as both a driving touch electrode and a sensing touch electrode. For example, the touch sensing circuit applies a touch driving signal to one or more touch electrodes TE and detects a touch sensing signal by means of the touch electrode TE applied with the touch driving signal. The touch sensing circuit identifies the change in capacitance between a pointer such as a finger or a pen and the touch electrode TE based on the detected touch sensing signal to sense the presence of touch and/or the touch coordinate. In the self-capacitance based touch sensing manner, the driving touch electrode and the sensing touch electrode are not distinguished.

As described above, the display device according to the example embodiments of the present disclosure may sense the touch by the mutual-capacitance based touch sensing manner or the self-capacitance based touch sensing manner. However, in the following description, for the convenience of description, it will be described that the display device performs mutual-capacitance based touch sensing and includes a touch sensor structure therefor, as an example.

Hereinafter, a configuration of a sub pixel will be described in detail with reference to the drawings.

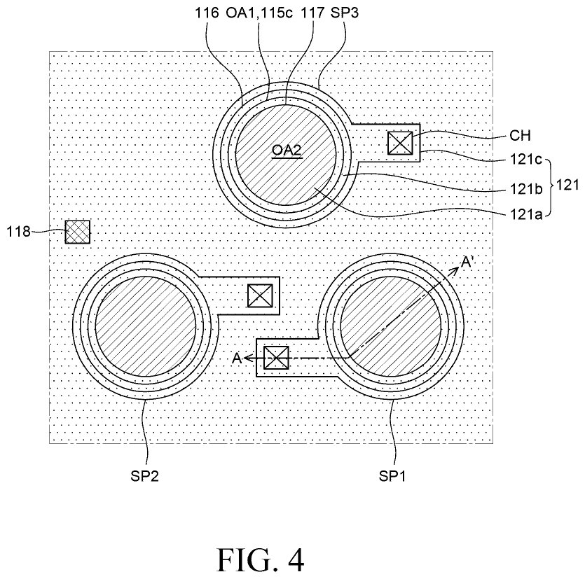

FIG. 4 is an example view illustrating a pixel structure of a display panel according to a first example embodiment of the present disclosure.

FIG. 4 illustrates a part of a display panel in which three sub pixels SP1, SP2, and SP3 are disposed as an example. Further, FIG. 4 illustrates a planar surface structure of a second bank 117 including a second open area OA2 which is a main emission area, an anode 121 with a side mirror structure, a first bank 116 disposed on a third area 121c of the anode 121, a third planarization layer 115c including a first open area OA1, and a spacer 118.

Referring to FIG. 4, the display panel according to the first example embodiment of the present disclosure may include a pixel area in which a plurality of sub pixels SP1, SP2, and SP3 is provided and a wiring area in which various signal lines are disposed.

A plurality of first sub pixels SP1, second sub pixels SP2, and third sub pixels SP3 may be disposed in the pixel area.

For example, the first sub pixel SP1 may be a red sub pixel.

For example, the second sub pixel SP2 may be a green sub pixel.

For example, the third sub pixel SP3 may be a blue sub pixel.

For example, the first sub pixel SP1, the second sub pixel SP2, and the third sub pixel SP3 may have a circular shape or an oval shape, but are not limited thereto and may have a polygonal shape, such as a rectangular shape or a shape in which various shapes are mixed.

At this time, a shape of the sub pixels SP1, SP2, and SP3 is defined by the shape of the second open area OA2, but it is not limited thereto.

In FIG. 4, it is illustrated that one first sub pixel SP1, one second sub pixel SP2, and one third sub pixel SP3 configure one pixel, but is not limited thereto. For example, a white fourth sub pixel may be added to the first sub pixel SP1, the second sub pixel SP2, and the third sub pixel SP3.

In the meantime, according to one or more aspects of the present disclosure, due to the side mirror SM structure of the anode 121, a reflective emission area is added as well as a main emission area so that the emission area may be expanded as compared with each of the sub pixels SP1, SP2, and SP3. The side mirror structure will be described in detail below.

As illustrated in FIG. 4, the third planarization layer 115c in which the anode 121 with the side mirror structure is disposed may include a first open area OA1 obtained by removing (opening) a part of the third planarization layer 115c corresponding to a main emission area, a reflective emission area, and a second non-emission area of the sub pixels SP1, SP2, and SP3.

As described above, according to one or more aspects of the present disclosure, the side mirror structure of the anode 121 is used to increase an amount of extracted amount of the display device and a color on encapsulation (COE) structure in which the color filter layer is disposed on the encapsulation unit is applied to reduce the thickness of the display panel. Further, according to one or more aspects of the present disclosure, a first bank 116 which is black is applied on the anode 121 with a side mirror structure to improve a reflectance under the COE structure, which will be described in detail with reference to drawings.

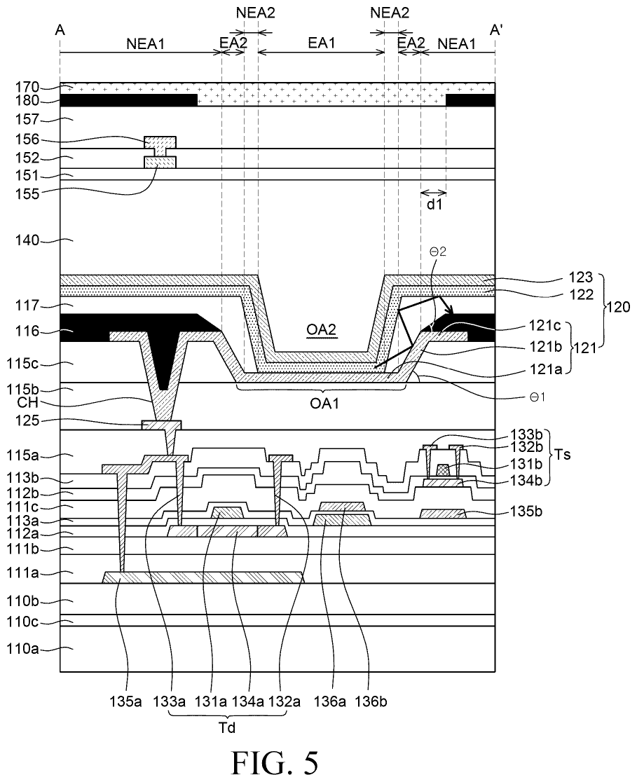

FIG. 5 is an example cross-sectional view taken along the line A-A′ of FIG. 4.

FIG. 5 illustrates a part of a cross-section of one sub pixel of a display panel according to the first example embodiment of the present disclosure. For example, FIG. 5 illustrates a part of a cross-section obtained by cutting a center of the first sub pixel SP1 of FIG. 4 approximately in a left-right direction.

Referring to FIG. 5, the driving transistor Td, the switching transistor Ts, and the light emitting diode 120 may be disposed above substrates 110a, 110b, and 110c.

For example, the substrates 110a, 110b, and 110c may include a first substrate 110a, a second substrate 110b, and an interlayer insulating layer 110c. The interlayer insulating layer 110c may be disposed between the first substrate 110a and the second substrate 110b.

As described above, the substrates 110a, 110b, and 110c is configured by the first substrate 110a, the second substrate 110b, and the interlayer insulating layer 110c to effectively suppress permeation of the moisture. For example, the first substrate 110a and the second substrate 110b may be polyimide (PI) substrates, but are not limited thereto.

Further, the substrates 110a, 110b, and 110c may use a flexible material to become flexible substrates. By using this, a foldable display panel which is foldable or bendable may be manufactured.

A plurality of transistors, such as a driving transistor Td or a switching transistor Ts, may be disposed above the substrates 110a, 110b, and 110c.

A multi-buffer layer 111a is disposed on the second substrate 110b and an active buffer layer 111b may be disposed on the multi-buffer layer 111a.

In the meantime, a first light shielding layer 135a may be disposed above the second substrate 110b. However, it is not limited thereto and the first light shielding layer 135a may be disposed on the multi-buffer layer 111a.

The first light shielding layer 135a may serve as a light shield.

The multi-buffer layer 111a may be disposed on the first light shielding layer 135a.

The active buffer layer 111b may be disposed above the multi-buffer layer 111a.

A first active layer 134a of the driving transistor Td may be disposed above the active buffer layer 111b.

A first gate insulating layer 112a may be disposed on the first active layer 134a.

Further, a first gate electrode 131a of the driving transistor Td may be disposed on the first gate insulating layer 112a.

Further, for example, a gate material layer 136a may be disposed on the first gate insulating layer 112a in a position different from a forming position of the driving transistor Td. For example, the gate material layer 136a may be a first storage electrode, but is not limited thereto.

The first interlayer insulating layer 113a may be disposed on the first gate electrode 131a.

A metal layer 136b may be disposed on the first interlayer insulating layer 113a. For example, the metal layer 136b may be a second storage electrode, but is not limited thereto.

In this case, the metal layer 136b may configure the storage capacitor together with the gate material layer 136a, but is not limited thereto.

Further, for example, a second light shielding layer 135b may be disposed on the first interlayer insulating layer 113a in a position different from a forming position of the metal layer 136b.

The buffer layer 111c may be disposed on the metal layer 136b and the second light shielding layer 135b.

A second active layer 134b of the switching transistor Ts may be disposed on the buffer layer 111c.

A second gate insulating layer 112b may be disposed on the second active layer 134b.

Further, a second gate electrode 131b of the switching transistor Ts may be disposed on the second gate insulating layer 112b.

The second interlayer insulating layer 113b may be disposed on the second gate electrode 131b.

A first source electrode 132a and a first drain electrode 133a of the driving transistor Td may be disposed on the second interlayer insulating layer 113b. Further, a second source electrode 132b and a second drain electrode 133b of the switching transistor Ts may be disposed on the second interlayer insulating layer 113b.

At this time, for example, the first source electrode 132a and the first drain electrode 133a may be electrically connected to one side and the other side of the first active layer 134a through contact holes provided in the second interlayer insulating layer 113b, the second gate insulating layer 112b, the buffer layer 111c, the first interlayer insulating layer 113a, and the first gate insulating layer 112a.

Further, for example, a part of the first drain electrode 133a may be electrically connected to one side of the first light shielding layer 135a through contact holes provided in the second interlayer insulating layer 113b, the second gate insulating layer 112b, the buffer layer 111c, the first interlayer insulating layer 113a, the first gate insulating layer 112a, the active buffer layer 111b, and the multi-buffer layer 111a.

Further, for example, the second source electrode 132b and the second drain electrode 133b may be electrically connected to one side and the other side of the second active layer 134b, through contact holes provided in the second interlayer insulating layer 113b and the second gate insulating layer 112b, respectively.

A part of the first active layer 134a which overlaps the first gate electrode 131a is a channel region. For example, one of the first source electrode 132a and the first drain electrode 133a is connected to a source region at one side of the channel region in the first active layer 134a and the other one is connected to a drain region at the other side of the channel region in the first active layer 134a.

Further, a part of the second active layer 134b which overlaps the second gate electrode 131b is a channel region. For example, one of the second source electrode 132b and the second drain electrode 133b is connected to the source region at one side of the channel region in the second active layer 134b and the other one is connected to the drain region at the other side of the channel region in the second active layer 134b.

Even though it is not illustrated, a protection layer may be disposed on the first source electrode 132a, the first drain electrode 133a, the second source electrode 132b, and the second drain electrode 133b.

The planarization layers 115a and 115b may be disposed above the first source electrode 132a, and the first drain electrode 133a and the second source electrode 132b and the second drain electrode 133b. For example, the planarization layers 115a and 115b may include a first planarization layer 115a and a second planarization layer 115b.

The first planarization layer 115a may be disposed on the protection layer.

The connection electrode 125 may be disposed on the first planarization layer 115a.

For example, the connection electrode 125 may be electrically connected to one of the first source electrode 132a and the first drain electrode 133a through a contact hole CH provided in the first planarization layer 115a.

The second planarization layer 115b may be disposed on the connection electrode 125.

A third planarization layer 115c may be disposed on the second planarization layer 115b.

The third planarization layer 115c may be configured by an organic material, such as acrylic-based resin or epoxy-based resin, and for example, may be configured by photo acryl (PAC). For the convenience of description, the third planarization layer 115c may be referred to as a planarization layer.

For example, the third planarization layer 115c may include a first open area OA1 obtained by removing (opening) a part of the third planarization layer 115c corresponding to a main emission area EA1, a reflective emission area EA2, and a second non-emission area NEA2 of the sub pixel.

In the plan view, the first open area OA1 may have an approximately (or overall) circular shape or an oval shape, but is not limited thereto and may have a polygonal shape, such as a rectangular shape.

The third planarization layer 115c may include a top surface and a side portion.

The top surface of the third planarization layer 115c is a surface located at the top of the third planarization layer 115c and is substantially parallel to the second substrate 110b.

Further, the side portion of the third planarization layer 115c may be a surface extending from the top surface of the third planarization layer 115c to a side surface. For example, a side portion of the third planarization layer 115c may have a predetermined taper angle. For example, the side portion of the third planarization layer 115c may have a taper angle θ1 of 45° to 65°, but is not limited thereto.

Here, the taper angle (or tangential angle) refers to an angle between a surface of an upper portion of the second planarization layer 115b on which the third planarization layer 115c is disposed and a side portion of the third planarization layer 115c.

In the plan view, the side portion of the third planarization layer 115c may have an approximately (or overall) circular shape or oval shape, like the edge of the first open area OA1, but is not limited thereto and may have a polygonal shape, such as a rectangular shape.

For example, the anode 121 may be disposed on a part of the top surface and the side portion of the third planarization layer 115c and a part of the top surface of the second planarization layer 115b. For example, the anode 121 may be disposed on the first open area OA1 and a part of the top surface and the side portion of the third planarization layer 115c. For example, the anode 121 which is disposed in the first open area OA1 may be in contact with the top surface of the second planarization layer 115b.

That is, for example, the anode 121 may include a first area 121a which is disposed in the first open area OA1 and has a surface substantially parallel to a surface of the second substrate 110b and a second area 121b which extends from the first area 121a so that a surface has a predetermined angle with respect to the second substrate 110b. At this time, for example, the first area 121a of the anode 121 may be disposed to correspond to the first open area OA1. Further, the second area 121b of the anode 121 may be disposed to correspond to a side portion of the third planarization layer 115c. Therefore, the second area 121b of the anode 121 may be referred to as a side portion of the anode 121.

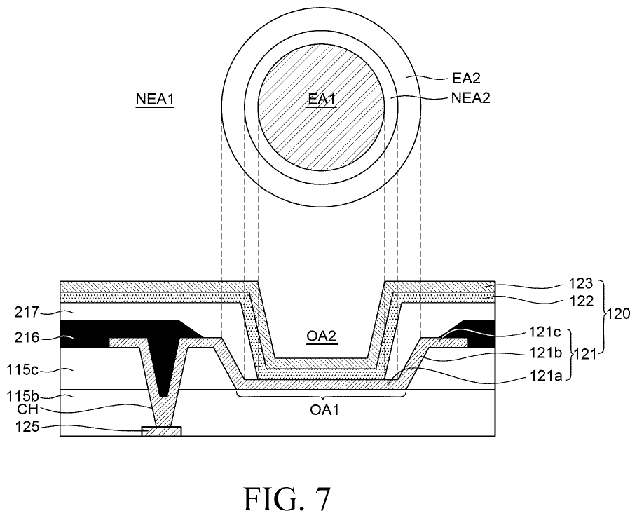

In one or more aspects of the present disclosure, the second area 121b of the anode 121 is a part having a side-mirror shape and may configure the SM structure. For example, the SM structure of the anode 121 may form a reflective emission area EA2. The reflective emission area EA2 will be described in detail below with reference to FIG. 7.

The SM structure of the anode 121 increases the amount of extracted light to improve the viewing angle luminance and luminous efficiency. In the meantime, the amount of extracted light is increased thereby implementing the low power. Therefore, the use of fossil fuels for power generation is reduced to implement ESG (Environment/Social/Governance) by reducing greenhouse gas emissions.

If the increased amount of extracted light is mainly directed to the front, it contributes to improving the luminous efficiency, and if it is directed diagonally, it may contribute to improving viewing angle luminance.

The anode 121 may include a third area 121c which extends from the second area 121b so that a surface is substantially parallel to a surface of the second substrate 110b. The third area 121c may be disposed to correspond to the top surface of the third planarization layer 115c.

As described above, in one sub pixel, the second planarization layer 115b and the third planarization layer 115c may include at least one contact hole CH spaced apart from the first open area OA1. Therefore, the driving transistor Td and the anode 121 are electrically connected through a contact hole CH.

The first bank 116 may be disposed on the third planarization layer 115c while covering a part of the anode 121.

The first bank 116 may cover the third area 121c of the anode 121. Further, the first bank 116 may cover the third area 121c of the anode 121, including the contact hole CH. The first bank 116 may cover the third area 121c of the anode 121 and the top surface of the third planarization layer 115c.

The first bank 116 of the present disclosure is configured by (or includes) black resin and may serve to improve the reflective visibility in the color on encapsulation (COE) structure. For example, the first bank 116 is configured such that the black pigment is dispersed in an organic material, but is not limited thereto and as long as the first bank has a black color, the first bank may be configured by an arbitrary material. Further, for example, the organic material may be cardo-based polymer and polymer including epoxy acrylate, but is not limited thereto. As the first bank 116 includes a black material, reflection of external light, specifically, irregular reflection caused when the first bank 116 is formed of a transparent material, may be reduced.

Further, the first bank 116 may be formed by a plurality of layers. For example, a lower bank layer is formed of a black material and an upper bank layer disposed thereabove may be formed of a transparent material. Further, the upper bank layer may include a spacer 118. The spacer 118 may serve to suppress damages generated on the configurations disposed above the substrates 110a, 110b, and 110c caused when the mask used during the deposition of the organic layer 122 is in contact with the substrates 110a, 110b, and 110c.

For example, the first bank 116 may have a height of approximately 1.0 μm to 2.0 μm. Accordingly, a height of the second bank 117 disposed on the first bank 116 may be lowered accordingly, but is not limited thereto.

Further, the first bank 116 may have the same height along the periphery of the second open area OA2, but is not limited thereto and may have different heights along steps of configurations located therebelow.

Specifically, when the COE structure is applied in the SM structure, if the black bank is not used, totally reflected light enters the TFT element, which may deteriorate the device reliability. Therefore, according to one or more aspects of the present disclosure, the first bank 116 is configured by a black based resin to block the light entering the TFTs Td and Ts to improve the device reliability (see the arrow of FIG. 5). Further, according to one or more aspects of the present disclosure, when the COE structure is applied in the SM structure, the first bank 116 is configured by a black based resin, so that the reflectance increase by the second area 121b and the third area 121c of the anode 121 may be improved.

Specifically, according to one or more aspects of the present disclosure, when the COE structure is applied in the SM structure, in order to solve a problem in that light absorption occurs in the first bank 116 before reflecting by the anode 121, the first bank 116 may be disposed on the third area 121c so as to cover the third area 121c of the anode 121.

In the first example embodiment of the present disclosure, the first bank 116 may be disposed so as to cover the entire third area 121c of the anode 121, but is not limited thereto and the first bank 116 may expose a part of the third area 121c of the anode 121 in consideration of the process error.

That is, an end of the first bank 116 may match an end of the third area 121c, but is not limited thereto.

For example, a side portion of the first bank 116 may have a taper angle θ2 of 30° to 40° and the taper angle θ2 of the first bank 116 may be smaller than the taper angle θ1 of the third planarization layer 115c, but is not limited thereto.

Further, the side portion of the first bank 116 may have the same taper angle θ2 along the periphery of the second open area OA2, but is not limited thereto and a part may have a taper angle θθ2 different from that of the other. For example, when the viewing angle is considered, the taper angle θ2 of the side portion of the first bank 116 with respect to the left and right sides of the sub pixel may be different from the taper angle θ2 of the side portion of the first bank 116 with respect to the upper and lower sides.

In the meantime, the second bank 117 may be disposed on the first bank 116.

The second bank 117 may cover the first bank 116 and the second area 121b of the anode 121. Further, the second bank 117 may cover a part of the first area 121a of the anode 121. For example, the second bank 117 may cover a part an edge of the first area 121a of the anode 121.

At this time, a part of the second bank 117 corresponding to the main emission area EA1 of the sub pixel may be open. That is, the second bank 117 may include a second open area OA2 obtained by removing (opening) a part of the second bank 117 corresponding to the main emission area EA1 of each sub pixel. For example, the first open area OA1 may have a width and an area larger than the second open area OA2.

The reflective emission area EA2 does not overlap the main emission area EA1 and may be located while enclosing the main emission area EA1.

The sub pixels may be divided by the main emission area EA1.

Next, the second bank 117 may include a top surface, a side portion, and a bottom surface.

For example, the top surface of the second bank 117 is a surface located on the top of the second bank 117 and is substantially parallel to the second substrate 110b. The top surface of the second bank 117 may correspond to the top surface of the first bank 116 and the third planarization layer 115c.

The side portion of the second bank 117 may be a surface extending from the top surface of the second bank 117 to a side surface. The side portion of the second bank 117 may have a predetermined taper angle. For example, a side portion of the second bank 117 may have a taper angle of 45° to 65°, but the present disclosure is not limited thereto. The side portion of the second bank 117 may correspond to the side portion of the third planarization layer 115c.

For example, the bottom surface of the second bank 117 may correspond to a surface which abuts with the first area 121a and the second area 121b of the anode 121, the top surface and the side surface of the first bank 116, and the top surface of the third planarization layer 115c.

For example, a part of the first area 121a of the anode 121 may be exposed by the second open area OA2.

The second bank 117 may be formed of a PI based material, but is not limited thereto.

Further, for example, the side portion of the second bank 117 has a circular shape or an oval shape, substantially the same as the edge of the second open area OA2, but is not limited thereto and may have a polygonal shape, such as a rectangular shape.

In the meantime, the organic layer 122 may be disposed in the second open area OA2 of the second bank 117 or in the vicinity thereof. For example, the organic layer 122 may be disposed on the first area 121a of the anode 121 exposed through the second open area OA2 of the second bank 117. Further, for example, the organic layer 122 may be disposed in the second open area OA2 of the second bank 117.

The organic layer 122 may be disposed only in the second open area OA2, but the present disclosure is not limited thereto and a part thereof may also be disposed on a top surface and a side portion of the second bank 117 other than the second open area OA2.

The cathode 123 may be disposed on the organic layer 122.

The light emitting diode 120 may be configured by the anode 121, the organic layer 122, and the cathode 123.

For example, the main emission area EA1 may be formed by the light emitting diode 120 provided in the second open area OA2.

The encapsulation unit 140 may be disposed above the above-described light emitting diode 120.

The light emitting diode 120 may react to external moisture and oxygen due to a characteristic of the organic material of the organic layer 122 to cause dark-spot or pixel shrinkage. In order to suppress this problem, the encapsulation unit 140 may be disposed above the cathode 123. Even though it is not illustrated, the encapsulation unit 140 may be configured by a first inorganic insulating film, a foreign material compensation layer, and a second inorganic insulating film, but is not limited thereto.

The first inorganic insulating film may be disposed above the substrate 110a, 110b, and 110c in which the cathode 123 is disposed to be adjacent to the light emitting diode 120.

For example, the first inorganic insulating film may be configured by an inorganic insulating material on which low-temperature deposition is allowed, such as silicon nitride (SiNx), silicon oxide (SiOx), silicon oxynitride (SiON), or aluminum oxide (Al₂O₃). The first inorganic insulating film is deposited under a low temperature atmosphere so that the damage of the organic layer 122 including an organic material vulnerable to the high temperature atmosphere during the deposition may be suppressed.

A foreign material compensation layer may be disposed to have a smaller area than the first inorganic insulating film and may be configured to expose both ends of the first inorganic insulating film. The foreign material compensation layer may be formed of an organic insulating material, such as acrylic resin, epoxy resin, polyimide, polyethylene, or silicon oxy carbon (SiOC).

In the meantime, when the foreign material compensation layer is formed by an inkjet method, one or more dams may be disposed in a boundary area of the non-active area and the active area or a dam area corresponding to a partial area in the non-active area may be disposed. In such a dam area, a primary dam adjacent to the active area and a secondary dam adjacent to the pad unit may be disposed.

When a liquid type foreign material compensation layer is formed in the active area, one or more dams disposed in the dam area suppress the liquid type foreign material compensation layer from collapsing in the direction of the non-active area to invade the pad unit.

The primary dam and/or secondary dam may be configured as a single layer or a multi-layered structure.

Further, the foreign material compensation layer including an organic material may be located only on an inner surface of the primary dam.

Further, the second inorganic insulating film may be disposed so as to cover an upper surface and a side surface of each of the first inorganic insulating film and the foreign material compensation layer. The second inorganic insulating film may serve to minimize or block the permeation of the external moisture or oxygen into the first inorganic insulating film and the foreign material compensation layer. At this time, the second inorganic insulating film is formed of an inorganic insulating material, such as silicon nitride (SiNx), silicon oxide (SiOx), silicon oxynitride (SiON), or aluminum oxide (Al₂O₃).

A touch buffer film 151 may be disposed on the encapsulation unit 140.

A bridge pattern 155 may be disposed on the touch buffer film 151. However, it is not limited thereto and a touch electrode (or a touch line) may be disposed on the touch buffer film 151.

The touch buffer film 151 may be located between the bridge pattern 155 and the encapsulation unit 140.

The bridge pattern 155 may be disposed above the encapsulation unit 140 without having the touch buffer film 151.

The bridge pattern 155 may have a single-layer or multi-layered structure formed of a metal having strong corrosion resistance and acid resistance, such as aluminum (Al), titanium (Ti), copper (Cu), or molybdenum (Mo).

The touch insulating film 152 may be disposed on the bridge pattern 155.

For example, the touch insulating film 152 may use an organic film or an inorganic film which may be formed by a low temperature process. When the organic film is used for the touch insulating film 152, after coating the organic film above the substrates 110a, 110b, and 110c, the organic film is cured at a temperature of 100° C. or lower to form the touch insulating film 152 to suppress the damage of the organic layer 122 vulnerable to the high temperature. When the inorganic film is used for the touch insulating film 152, in order to suppress the damage of the organic layer 122 vulnerable to the high temperature, a low temperature chemical vapor deposition process and a washing process are repeated at least twice to form the touch insulating film 152 with a multi-layered structure.

A partial area of the touch insulating film 152 is selectively removed to form a touch contact hole to expose a part of the bridge pattern 155.

A touch electrode (or a touch line) 156 may be disposed on the touch insulating film 152. However, it is not limited thereto and the bridge pattern may be disposed on the touch insulating film 152.

For example, the touch electrode 156 may be electrically connected to the bridge pattern 155 through the touch contact hole.

Further, the touch planarization layer 157 may be disposed on the touch electrode 156, but is not limited thereto and the touch planarization layer may be omitted.

A black matrix 180 may be disposed on the touch planarization layer 157.

The black matrix 180 may be located above the touch electrode 156.

The black matrix 180 may be located in the first non-emission area NEA1.

According to one or more aspects of the present disclosure, the first bank 116 which is black is disposed below the black matrix 180 so that the width of the black matrix 180 may be reduced as compared with the related art so that a wide viewing angle may be ensured. That is, a critical dimension (CD) of the black matrix 180 may be smaller than a CD of the first bank 116. For example, according to the first example embodiment of the present disclosure, the black matrix 180 may have a first distance d1 from an end of the first bank 116, that is, a boundary of the second area 121b and the third area 121c of the anode 121.

The color filter layer 170 may be disposed in the main emission area EA1, the first non-emission area NEA1, the reflective emission area EA2, and the second non-emission area NEA2 between the black matrixes 180.

For example, the color filter layer 170 may include a red color filter layer, a green color filter layer, and a blue color filter layer, but is not limited thereto and may further include a white color filter layer.

The black matrix 180 may be disposed on the boundary of color filter layer 170 with different colors. Therefore, the black matrix 180 may define a sub pixel area. Sub pixel areas defined by the black matrix 180 may be a red sub pixel area, a green sub pixel area, and a blue sub pixel area. Further, the sub pixel area may further include a white sub pixel area. That is, an area in which the red color filter layer is disposed corresponds to a red sub pixel area, an area in which the green color filter layer is disposed corresponds to a green sub pixel area, and an area in which a blue color filter layer is disposed corresponds to a blue sub pixel area. Further, an area in which a white color filter layer is disposed corresponds to a white sub pixel area.

For example, in the area in which the red color filter layer is disposed, red light is emitted, in the area in which the green color filter layer is disposed, green light is emitted, in the area in which the blue color filter layer is disposed, blue light is emitted, and in the area in which the white color filter layer is disposed, white light may be emitted.

In the meantime, as described above, according to one or more aspects of the present disclosure, the anode 121 has a side mirror (SM) structure so that the amount of extracted light may be increased. That is, the second area 121b of the anode 121 including a reflective layer serves as a side mirror so that light which is generated in the light emitting diode 120 to be discharged to the second area 121b is reflected and extracted in the front surface to improve the efficiency of the display device. Further, the color filter layer 170 and the black matrix 180 are disposed above the encapsulation unit 140 to remove the polarizer, so that the luminous efficiency is improved and the thickness of the display panel may be reduced. Accordingly, light-weight and slim design may be implemented.

Further, according to one or more aspects of the present disclosure, when the COE structure is applied in the SM structure, the first bank 116 which is black is formed on the third area 121c so as to cover the third area 121c of the anode 121 so that the reflectance increase by the second area 121b and the third area 121c of the anode 121 may be improved. Therefore, light entering the TFT element is blocked to improve the device reliability.

In the first example embodiment of the present disclosure, the first bank 116 may be disposed so as to cover the entire third area 121c of the anode 121, but is not limited thereto and the first bank 116 may expose a part of the third area 121c of the anode 121 in consideration of the process error. This will be described in detail with reference to the drawing.

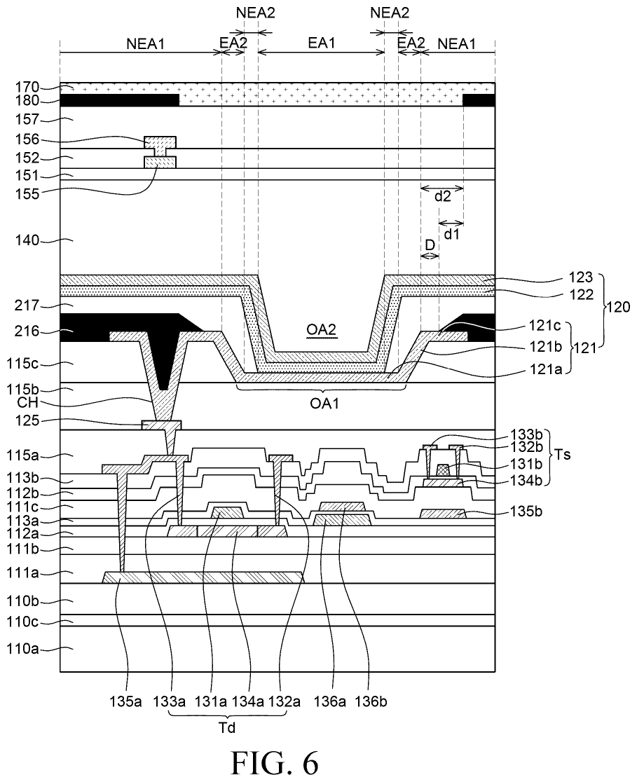

FIG. 6 is an example cross-sectional view illustrating a sub pixel structure of a second example embodiment of the present disclosure.

FIG. 7 is an example view illustrating an emission image taken along the cross-section of FIG. 6.

FIG. 6 illustrates a part of a cross-section of one sub pixel of a display panel according to the second example embodiment of the present disclosure.

FIG. 7 illustrates a part of a cross-section of one sub pixel of a display panel according to a second example embodiment of the present disclosure and an emission image corresponding thereto. In FIG. 7, for the sake of convenience, configurations above and below the light emitting diode 120 are not illustrated, but the present disclosure is not limited thereto.

The second example embodiment of the present disclosure of FIGS. 6 and 7 has a different configuration of a first bank 216 and a second bank 217 from that of the first example embodiment of the present disclosure of FIGS. 4 and 5 described above, but other configurations are substantially the same so that a redundant description will be omitted. Here, the descriptions of the same reference numerals may refer to the descriptions provided in connection with FIGS. 1 to 5.

Referring to FIGS. 6 and 7, as described above, a plurality of transistors, such as a driving transistor Td and a switching transistor Ts may be disposed above substrates 110a, 110b, and 110c.

The first planarization layer 115a may be disposed above the driving transistor Td and the switching transistor Ts.

The connection electrode 125 may be disposed on the first planarization layer 115a.

The second planarization layer 115b may be disposed on the connection electrode 125.

The third planarization layer 115c may be disposed on the second planarization layer 115b.

For example, the third planarization layer 115c may include a first open area OA1 obtained by removing (opening) a part of the third planarization layer 115c corresponding to a main emission area EA1, a reflective emission area EA2, and a second non-emission area NEA2 of the sub pixel.

In the plan view, the first open area OA1 may have approximately (or overall) a circular shape or an oval shape, but is not limited thereto and may have a polygonal shape, such as a rectangular shape.

The third planarization layer 115c may include a top surface and a side portion.

For example, the anode 121 may be disposed on a part of the top surface and the side portion of the third planarization layer 115c and a part of the top surface of the second planarization layer 115b.

That is, for example, the anode 121 may include a first area 121a which is disposed in the first open area OA1 and has a surface substantially parallel to a surface of the second substrate 110b and a second area 121b which extends from the first area 121a so that a surface has a predetermined angle with respect to the second substrate 110b.

In one or more aspects of the present disclosure, the second area 121b of the anode 121 is a part having a side-mirror shape and may configure the SM structure. For example, the SM structure of the anode 121 may form a reflective emission area EA2. At this time, for example, the reflective emission area EA2 takes along an outline of the main emission area EA1 so that when the light emitting diode 120 emits light, the reflective emission area may be shown as an emission image having a circular annular shape (or circular ring shape) without break or circular annular with break. However, the present disclosure is not limited thereto and when the first open area OA1 has a polygonal shape, the reflective emission area EA2 may be shown as polygonal annular emission image corresponding to the shape of the first open area OA1. If the reflective emission area EA2 is shown as an emission image with an annular shape with a break, the reflective emission area may enclose the outline of the main emission area EA1 with breaks in the middle.

As described above, the SM structure configured in the first open area OA1 forms the reflective emission area EA2. A part of light emitted by the light emitting diode 120 is reflected from the second area 121b of the anode 121 by the SM structure to form a circular annular reflective emission area EA2. Therefore, an amount of extracted light may be increased. However, the present disclosure is not limited thereto and when the first open area OA1 has a polygonal shape, the reflective emission area EA2 may have a polygonal annular shape corresponding to the shape of the first open area OA1.

The anode 121 may include a third area 121c which extends from the second area 121b so that a surface is substantially parallel to a surface of the second substrate 110b.

The first bank 216 may be disposed on the third planarization layer 115c while covering a part of the anode 121.

The first bank 216 of the second example embodiment of the present disclosure may cover a part of the third area 121c of the anode 121. The first bank 216 of the second example embodiment of the present disclosure may cover a part of the third area 121c of the anode 121 and the top surface of the third planarization layer 115c, including the contact hole CH. As described, when the process error is considered, the first bank 216 of the second example embodiment of the present disclosure may expose the other part of the third area 121c of the anode 121.

Therefore, the first bank 216 according to the second example embodiment of the present disclosure may be spaced apart from the boundary of the second area 121b and the third area 121c of the anode 121 by a predetermined distance. For example, a distance D between the boundary of the second area 121b and the third area 121c and the first bank 216 is approximately 0.5 μm to 1.5 μm, but is not limited thereto. Here, the distance D may be the same for all sub pixels, but is not limited thereto and may vary for every sub pixel.

The first bank 216 may be configured by a black based resin.

As described above, the first bank 216 of the second example embodiment of the present disclosure may be disposed on the third area 121c so as to cover a part of the third area 121c of the anode 121.

For example, the side portion of the first bank 216 may have a taper angle of 30° to 40°, which may be smaller than the taper angle of the third planarization layer 115c, but is not limited thereto.

The second bank 217 may be disposed on the first bank 216.

The second bank 217 of the second example embodiment of the present disclosure may cover the first bank 216 and the other part of the second area 121b and the exposed third area 121c of the anode 121. Further, the second bank 217 of the second example embodiment of the present disclosure may cover a part of the edge of the first area 121a of the anode 121.

The second bank 217 may include a second open area OA2 obtained by removing (opening) a part of the second bank 217 corresponding to the main emission area EA1 of each sub pixel. For example, in the plan view, the second open area OA2 may have a circular shape or an oval shape, but is not limited thereto, and may have a polygonal shape such as a rectangular shape.

In the meantime, the main emission area EA1 may have a shape corresponding to a shape of the second open area OA2. When a shape of an arbitrary component corresponds to a shape of the other component, it means that the shape of the arbitrary component has the same shape as the other component, or has the same shape, but has a different size, or a shape of the arbitrary component is formed by transferring the shape of the other component by an arbitrary method. Accordingly, the shape of the main emission area EA1 is substantially understood to be obtained by transferring a shape of the second open area OA2 by light emitted from the organic layer 122 located in the second open area OA2.

The reflective emission area EA2 does not overlap the main emission area EA1 and may be located while enclosing the main emission area EA1.

The sub pixels may be divided by the main emission area EA1.

For example, a part of the first area 121a of the anode 121 may be exposed by the second open area OA2.

Further, for example, the side portion of the second bank 217 may have a circular shape or an oval shape, substantially the same as the edge of the second open area OA2, but is not limited thereto and may have a polygonal shape, such as a rectangular shape.

The encapsulation unit 140 may be disposed above the above-described light emitting diode 120.

A touch sensor layer configured by a touch buffer film 151, a bridge pattern 155, a touch insulating film 152, a touch electrode 156, and a touch planarization layer 157 may be disposed above the encapsulation unit 140.

A black matrix 280 may be disposed on the touch planarization layer 157.

According to one or more aspects of the present disclosure, the first bank 216 which is black is disposed below the black matrix 280 so that the width of the black matrix 280 may be reduced as compared with the related art so that a wide viewing angle may be ensured. For example, according to the second example embodiment of the present disclosure, the black matrix 280 has a first distance d1 from an end of the first bank 216 and may have a second distance d2 from the boundary of the second area 121b and the third area 121c. According to the second example embodiment of the present disclosure, the width of the black matrix 280 may be further reduced as much as the distance D, as compared with the first example embodiment described above.

The color filter layer 170 may be disposed between the black matrices 280.

In the meantime, according to one or more aspects of the present disclosure, a display device in which a light receiving device is located behind the display panel so that the light receiving device which needs to receive light from the front surface is not exposed to the front surface is provided, which will be described in detail with reference to the drawings.

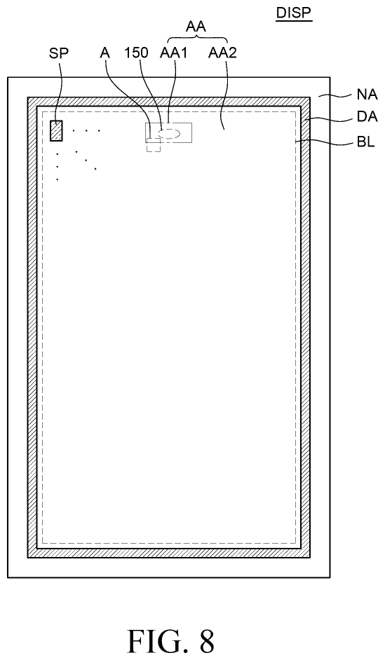

FIG. 8 is an example plan view schematically illustrating a display device according to a third example embodiment of the present disclosure.

Referring to FIG. 8, a display device according to a third example embodiment of the present disclosure may include a display panel DISP which displays images and a light receiving device 150 which receives light.

As described above, the display panel DISP may include an active area AA in which images are displayed and a non-active area NA which is an outer area of an outer boundary line BL of the active area AA.

Further, the display panel DISP may include a dam area DA in which a dam which suppresses any layer in the active area AA from extending beyond the display panel DISP is disposed.

Even though in FIG. 8, it is illustrated that the non-active area NA encloses a quadrangular active area AA, shapes and placements of the active area AA and the non-active area NA are not limited to the example illustrated in FIG. 8. That is, the active area AA and the non-active area NA may have shapes suitable for a design of an electronic device including the display device. For example, an example shape of the active area AA may be a pentagon, a hexagon, a circle, or an oval.

In the meantime, referring to FIG. 8, the active area AA may include a first active area AA1 and a second active area AA2, but is not limited thereto.

The light receiving device 150 is a device which receives light to perform a determined function. For example, the light receiving device 150 may include one or more of cameras and proximity sensors.

The light receiving device 150 is a device which requires light reception, but may be disposed on the rear surface of the display panel DISP, that is behind (below) the display panel DISP. For example, the light receiving device 150 may be disposed in an opposite side to a viewing surface of the display panel DISP. The light receiving device 150 is not exposed on the front surface of the display device. Accordingly, when a user views a front surface of the display device, the light receiving device 150 is not visible.

Here, a camera which is located behind (below) the display panel DISP is a front camera which captures the front and may also be considered as a camera lens.

The light receiving device 150 may be disposed so as to overlap the active area AA of the display panel DISP. For example, the light receiving device 150 may be disposed in the active area AA.

Here, an area overlapping the light receiving device 150 in the active area AA is referred to as a first active area AA1 and the other area may be referred to as a second active area AA2. Therefore, the light receiving device 150 may be located to overlap the first active area AA1 of the active area AA. In other words, the light receiving device 150 may be located in the first active area AA1 of the active area AA. The first active area AA1 is an area overlapping the light receiving device 150 so that a transmittance of the first active area AA1 of the active area AA needs to be better than the transmittance of the second active area AA2 which does not overlap the light receiving device 150.

In order to improve the transmittance of the first active area AA1 which overlaps the light receiving device 150, the first active area AA1 and the second active area AA2 may have different resolution, different sub pixel placement structures, different number of sub pixels for every unit area, different electrode structures, different line structures, different electrode placement structures, or different wiring line placement structures. However, the present disclosure is not limited thereto.

For example, the number of sub pixels for every unit area in the first active area AA1 may be smaller than the number of sub pixels for every unit area in the second active area AA2. Accordingly, a resolution of the first active area AA1 may be lower than a resolution of the second active area AA2. For example, in the second active area AA2, pixels per inch (PPI) is 400 or higher, but in the first active area AA1, PPI may be 200 or higher, but is not limited thereto.

For example, as a light receiving device 150 which is located below the display panel DISP without being exposed to the outside, the camera is referred to as an under display camera (UDC). Further, as the light receiving device 150, an IR sensor is also referred to as an under display IR sensor (UDIR). However, the present disclosure is not applied only to the above-described UDC model or UDIR model.

In the case of the display device 100 according to the third example embodiment of the present disclosure, a bezel width may be smaller and a notch type display panel DISP does not need to be manufactured. Further, there is no restriction in the design due to the light receiving device 150 so that a degree of freedom of design may be increased.

In the meantime, even though in the display device according to the third example embodiment of the present disclosure, the light receiving device 150 is located behind the display panel DISP, the light receiving device 150 needs to normally receive light and perform the determined function. In the meantime, even though in the display device according to the third example embodiment of the present disclosure, the light receiving device 150 is located behind the display panel DISP and overlaps the active area AA, the light receiving device 150 needs to normally receive light and perform the determined function. Further, the image needs to be normally displayed in the active area AA.

Accordingly, the display device according to the third example embodiment of the present disclosure may have a structure which improves a transmittance of the first active area AA1 overlapping the light receiving device 150.

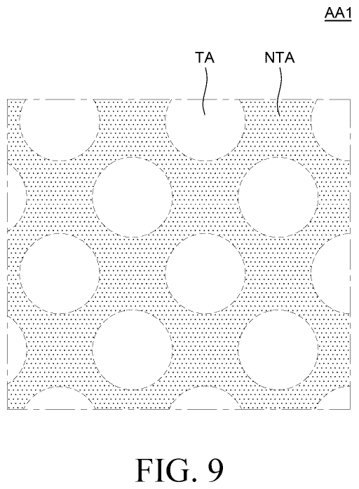

FIG. 9 is an example view illustrating a first active area of a display device of FIG. 8.

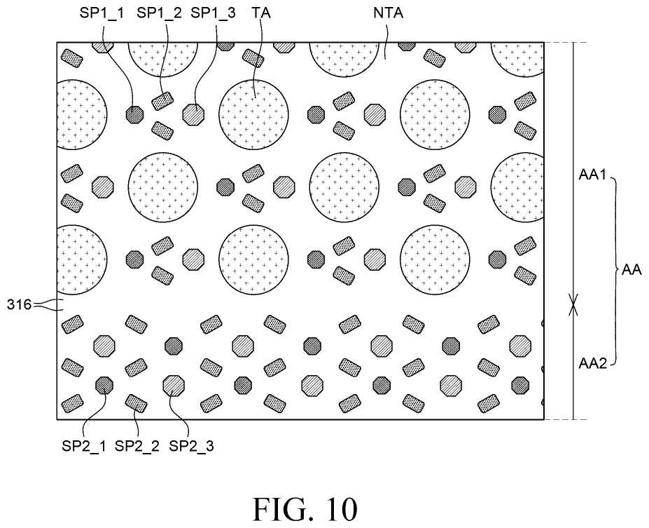

FIG. 10 is an example view illustrating a part A of FIG. 8.

In FIG. 10, as compared with FIG. 9, a part of the second active area AA2 and a pixel structure are additionally illustrated.

Referring to FIGS. 9 and 10, the active area AA may include a first active area AA1 overlapping the light receiving device and a second active area AA2 which is the remaining area.

The first active area AA1 may overlap the light receiving device.

The first active area AA1 may include a non-transmission area NTA and a transmission area TA. As described above, in the UDC model and the UDIR model, the first active area AA1 includes both an emission area for display, that is, the non-transmission area NTA and a transmission area TA in which the light receiving device 150 receives light.

The transmission area TA is a partial area which is included in the first active area AA1 and as an opaque configuration, such as the cathode, is removed, external light may be transmitted to the light receiving device.

For example, the transmission area TA may have a circular or oval shape, and is also referred to as a hole area.

Further, the non-transmission area NTA is the other partial area included in the first active area AA1 and a transistor of the transistor layer and a light emitting diode of the light emitting diode layer may be located in the non-transmission area.

The non-transmission area NTA may include a pixel area in which a plurality of sub pixels SP1_1, SP1_2, SP1_3; SP2_1, SP2_2, and SP2_3 is provided and a wiring area in which various signal lines are disposed.

When the transmission area TA is enclosed by the non-transmission area NTA, the first active area AA1 may include a plurality of separated transmission areas TA, but is not limited thereto.

In the first active area AA1, a plurality of first sub pixels SP1_1, SP1_2, and SP1_3 may be disposed in the pixel area. Further, for example, the first sub pixels SP1_1, SP1_2, and SP1_3 may include a first-first sub pixel SP1_1, a first-second sub pixel SP1_2, and a first-third sub pixel SP1_3.

In the second active area AA2, a plurality of second sub pixels SP2_1, SP2_2, and SP2_3 may be disposed in the pixel area. Further, for example, the second sub pixels SP2_1, SP2_2, and SP2_3 may include a second-first sub pixel SP2_1, a second-second sub pixel SP2_2, and a second-third sub pixel SP2_3.

For example, the first-first sub pixel SP1_1 and the second-first sub pixel SP2_1 may be red sub pixels.

For example, the first-second sub pixel SP1_2 and the second-second sub pixel SP2_2 may be green sub pixels.

For example, the first-third sub pixel SP1_3 and the second-third sub pixel SP2_3 may be blue sub pixels.

For example, the first-first sub pixel SP1_1 and the second-first sub pixel SP2_1 and the first-third sub pixel SP1_3 and the second-third sub pixel SP2_3 may have a circular shape or a polygonal shape, but are not limited thereto.

For example, the first-second sub pixel SP1_2 and the second-second sub pixel SP2_2 may have an oval shape or a substantial rectangular shape, but are not limited thereto.

In FIG. 3, it is illustrated that one first-first sub pixel SP1_1, two first-second sub pixels SP1_2 and one first-third sub pixel SP1_3 are gathered to form the first pixel and one second-first sub pixel SP2_1, two second-second sub pixels SP2_2, and one second-third sub pixel SP2_3 are gathered to form the second pixel. However, the present disclosure is not limited thereto.

Further, each of the first pixel disposed in the first active area AA1 and the second pixel disposed in the second active area AA2 have a rhombus shape, but are not limited thereto.

Further, the first pixel disposed in the first active area AA1 may be disposed to be enclosed by four transmission areas TA, but is not limited thereto.

As seen from FIG. 10, it is understood that the first pixel disposed in the first active area AA1 has the pixels per inch (PPI) lower than the second pixel disposed in the second active area AA2. Therefore, the transmittance of the first active area AA1 which overlaps the light receiving device may be improved.

As described above, in the third example embodiment of the present disclosure, in order to ensure the transmission area TA, the number of first pixels of the first active area AA1 which overlaps the light receiving device may be reduced. By doing this, the efficiency deviation is caused between the first active area AA1 and the second active area AA2. In this case, the visibility at the boundary of the first active area AA1 and the second active area AA2 may become an issue.

Therefore, according to the third example embodiment of the present disclosure, in the first sub pixels SP1_1, SP1_2, and SP1_3 of the first active area AA1, an anode with a side mirror (SM) structure may be formed on the side surface of the emission layer. Therefore, the light extraction efficiency of the first active area AA1 is improved to reduce the efficiency deviation and the visibility difference between the first active area AA1 and the second active area AA2 and the visibility difference between the transmission area TA and the non-transmission area NTA in the first active area AA1. By doing this, the degradation of the sharpness and the color sense is improved and the transmission area TA in which the light receiving device receives light is additionally ensured to improve an image quality of the light receiving device.

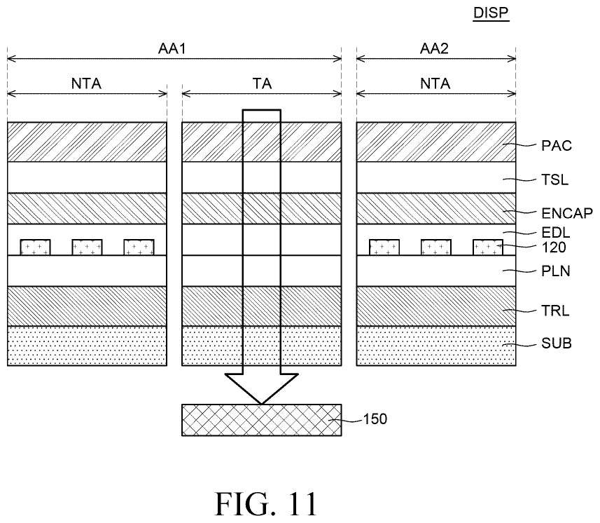

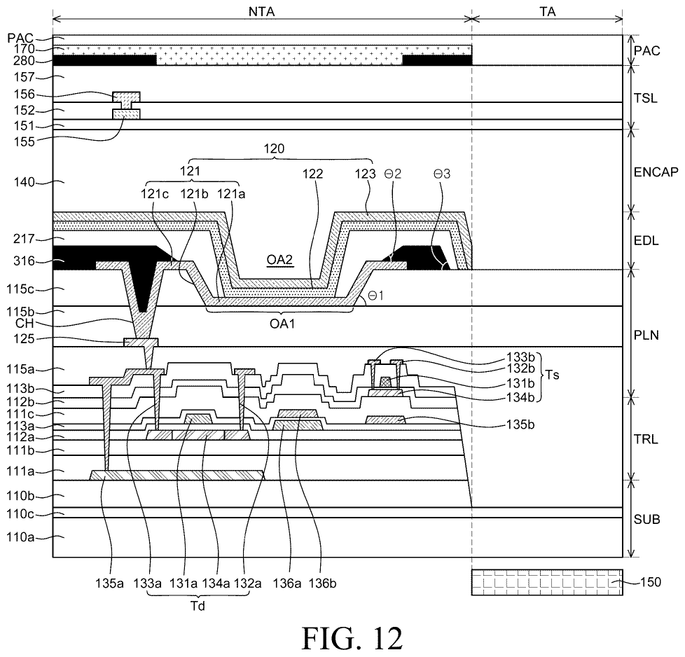

Further, according to the third example embodiment of the present disclosure, the COE structure in which the color filter layer is disposed above the encapsulation unit is applied to reduce the thickness of the display panel DISP. Further, according to the third example embodiment of the present disclosure, the black first bank is applied on the anode with the side mirror structure to improve the reflectance under the COE structure, which will be described in detail with reference to FIGS. 11 and 12.

FIG. 11 is an example view illustrating a cross-sectional structure of a non-transmission area and a transmission area in a first active area and a cross-sectional structure of a second active area, in a display device according to a third example embodiment of the present disclosure.

Referring to FIG. 11, the first active area AA1 of the display panel DISP may include a transmission area TA and a non-transmission area NTA. The second active area AA2 of the display panel DISP may be considered as a non-transmission area NTA.

Hereinafter, a lamination structure of the non-transmission area NTA and a lamination structure of the transmission area TA of the first active area AA1 and a lamination structure of the second active area AA2 will be described.

First, the lamination structure of the second active area AA2 is as follows.

In the second active area AA2, a transistor layer TRL is disposed above the substrate SUB and a planarization layer PLN may be disposed above the transistor layer TRL. Further, a light emitting diode layer EDL is disposed above the planarization layer PLN and an encapsulation layer ENCAP may be disposed above the light emitting diode layer EDL.

A touch sensor layer TSL is disposed above the encapsulation layer ENCAP and a protection layer PAC may be disposed above the touch sensor layer TSL.

In the second active area AA2, on the transistor layer TRL, various transistors, such as a driving transistor and a scan transistor for each sub pixel may be disposed and further various insulating films for forming the transistors may be disposed. Various insulating films may include organic films and inorganic films.

In the second active area AA2, various wiring lines, such as a data line, a gate line, or a driving voltage line, may be disposed on the transistor layer TRL.

In the second active area AA2, a light emitting diode 120 for each sub pixel may be disposed on the light emitting diode layer EDL. For example, an anode, a plurality of organic layers, and a cathode which configure the light emitting diode 120 may be disposed on the light emitting diode layer EDL.

In the second active area AA2, on the touch sensor layer TSL, the touch sensor may be disposed and a touch buffer film and a touch insulating film required to form the touch sensor may be further disposed.

Next, the lamination structure of the non-transmission area NTA of the first active area AA1 is substantially the same as the lamination structure of the second active area AA2 excluding the SM structure.

Referring to FIG. 11, in the non-transmission area NTA of the first active area AA1, a transistor layer TRL is disposed above the substrate SUB and a planarization layer PLN may be disposed above the transistor layer TRL.

A light emitting diode layer EDL is disposed above the planarization layer PLN and an encapsulation layer ENCAP may be disposed above the light emitting diode layer EDL. Further, a touch sensor layer TSL is disposed above the encapsulation layer ENCAP and a protection layer PAC is disposed above the touch sensor layer TSL.

The light emitting diode 120 is vulnerable to moisture or oxygen. For example, the encapsulation layer ENCAP suppresses the permeation of moisture or oxygen to suppress the light emitting diode 120 from being exposed to the moisture or oxygen. The encapsulation layer ENCAP may be formed by one layer or a plurality of layers.

In the non-transmission area NTA of the first active area AA1, on the transistor layer TRL, a plurality of transistors, such as a driving transistor and a scan transistor for each sub pixel are disposed and further various insulating films for forming the transistors may be disposed. Here, various insulating films may include organic films and inorganic films.

Further, in the non-transmission area NTA of the first active area AA1, various wiring lines, such as a data line, a gate line, or a driving voltage line, may be disposed on the transistor layer TRL.

Further, a first bank and a second bank may be disposed in the non-transmission area NTA of the first active area AA1.

In the non-transmission area NTA of the first active area AA1, the emitting diode 120 of each sub pixel may be disposed on the light emitting diode layer EDL. For example, an anode, a plurality of organic layers, and a cathode which configure the light emitting diode 120 may be disposed on the light emitting diode layer EDL. For example, in the non-transmission area NTA of the first active area AA1, the anode may have a side mirror (SM) structure in which a side surface of the emission layer has a mirror shape.

Further, in the non-transmission area NTA of the first active area AA1, the touch sensor TS may be disposed on the touch sensor layer TSL and a touch buffer film and a touch insulating film required to form the touch sensor TS may be further disposed.

Further, the lamination structure of the transmission area TA of the first active area AA1 is as follows.

Referring to FIG. 11, in the transmission area TA of the first active area AA1, a transistor layer TRL is disposed above the substrate SUB and a planarization layer PLN may be disposed above the transistor layer TRL.

A light emitting diode layer EDL is disposed above the planarization layer PLN and an encapsulation layer ENCAP may be disposed above the light emitting diode layer EDL. Further, a touch sensor layer TSL is disposed above the encapsulation layer ENCAP and a protection layer PAC may be disposed above the touch sensor layer TSL.

For example, in the transmission area TA of the first active area AA1, a plurality of transistors and wiring lines are not disposed on the transistor layer TRL. However, in the transmission area TA of the first active area AA1, various insulating films required to form the transistor may be disposed on the transistor layer TRL. Here, various insulating films may include organic films and inorganic films.

Further, a first bank and a second bank may not be disposed in the transmission area TA of the first active area AA1.

In the transmission area TA of the first active area AA1, the light emitting diode 120 of each sub pixel is not disposed on the light emitting diode layer EDL. For example, in the transmission area TA of the first active area AA1, the anode, the plurality of organic layers, and the cathode are not disposed on the light emitting diode layer EDL. However, the present disclosure is not limited thereto and in the transmission area TA of the first active area AA1, only some of the anode, the plurality of organic layers, and the cathode may be disposed on the light emitting diode layer EDL. For example, in the transmission area TA of the first active area AA1, only the organic layer or only the anode may extend to be disposed on the light emitting diode layer EDL.

In the transmission area TA of the first active area AA1, the touch sensor is not disposed on the touch sensor layer TSL. In the transmission area TA of the first active area AA1, the touch buffer film and the touch insulating film may be disposed on the touch sensor layer TSL.

Referring to FIG. 11, a metal material layer, between the metal material layer and an insulating material layer disposed in the non-transmission areas NTA of the first active area AA1 and the second active area AA2 is not disposed in the transmission area TA of the first active area AA1. However, the insulating material layer, between the metal material layer and an insulating material layer disposed in the non-transmission areas NTA of the first active area AA1 and the second active area AA2 may be disposed to extend to the transmission area TA of the first active area AA1.

In other words, the metal material layer is disposed in the non-transmission area NTA of the first active area AA1 and the non-transmission area NTA of the second active area AA2, but is not disposed in the transmission area TA of the first active area AA1. The insulating material layer may be commonly disposed in the non-transmission area NTA of the first active area AA1, the non-transmission area NTA of the second active area AA2, and in the transmission area TA of the first active area AA1, but the present disclosure is not limited thereto.

Further, the transmission area TA of the first active area AA1 may overlap the light receiving device 150 and external light may be transmitted to the light receiving device 150 through the transmission area TA of the first active area AA1. Accordingly, for the normal operation of the light receiving device 150, the transmittance of the transmission area TA of the first active area AA1 needs to be high.

FIG. 12 is an example cross-sectional view illustrating a sub pixel structure of a third example embodiment of the present disclosure.

FIG. 12 illustrates a part of the cross-section of the non-transmission area NTA and the transmission area TA of the first active area.

Referring to FIG. 12, a substrate SUB of the first active area may be divided into a non-transmission area NTA and a transmission area TA. A transistor layer TRL, a planarization layer PLN, a light emitting diode layer EDL, an encapsulation layer ENCAP, and a protection layer PAC may be disposed above the substrate SUB which is divided into the non-transmission area NTA and the transmission area TA.

In the transmission area TA, some configurations of the substrate SUB and the transistor layer TRL may not be disposed, but the present disclosure is not limited thereto.

First, the lamination structure of the non-transmission area NTA included in the first active area will be described.

As described above, the substrate SUB may include a first substrate 110a, a second substrate 110b, and an interlayer insulating layer 110c.

A plurality of transistors, such as a driving transistor Td or a switching transistor Ts, may be disposed on the transistor layer TRL.

The planarization layer PLN may be located above the transistor layer TRL.

The planarization layer PLN may include a first planarization layer 115a and a second planarization layer 115b. The first planarization layer 115a is formed of a PI based material and the second planarization layer 115b may be formed of a PAC based material. That is, the pixel shrinkage issue in the UDC model or the UDIR model is mainly caused by the outgas of the second planarization layer 115b rather than the first planarization layer 115a so that only the second planarization layer 115b may be configured by the PAC based material, but, it is not limited thereto.

The third planarization layer 115c may be disposed above the second planarization layer 115b.

The third planarization layer 115c may include a top surface and a side portion.

The light emitting diode layer EDL may be located above the third planarization layer 115c.

For example, the anode 121 may be disposed on a part of the top surface and the side portion of the third planarization layer 115c and a part of the top surface of the second planarization layer 115b.

That is, for example, the anode 121 may include a first area 121a which is disposed in the first open area OA1 and has a surface substantially parallel to a surface of the second substrate 110b and a second area 121b which extends from the first area 121a so that a surface has a predetermined angle with respect to the second substrate 110b.

In one or more aspects of the present disclosure, the second area 121b of the anode 121 is a part having a side-mirror shape and may configure the SM structure.

The anode 121 may include a third area 121c which extends from the second area 121b so that a surface is substantially parallel to a surface of the second substrate 110b.

The first bank 316 may be disposed on the third planarization layer 115c while covering a part of the anode 121. The first bank 316 according to the third example embodiment of the present disclosure covers a part of the third area 121c of the anode 121 and the top surface of the third planarization layer 115c, including the contact hole CH.

The first bank 316 may be configured by a black based resin.

For example, a side portion of the first bank 316 may have a taper angle θ2 of 30° to 40° and the taper angle θ2 of the first bank 316 may be smaller than the taper angle θ1 of the third planarization layer 115c, but is not limited thereto.

In the meantime, according to the third example embodiment of the present disclosure, the side portion of the first bank 316 adjacent to the transmission area TA has a taper angle θ3 different from that of the other side portion. That is, for example, the side portion of the first bank 316 adjacent to the transmission area TA may have a taper angle θ3 which is larger than a taper angle θ2 of the other portion and is smaller than a taper angle θ1 of the third planarization layer 115c, but is not limited thereto. Therefore, the side portion of the first bank may have the taper angle θ3 which is equal to the taper angle θ2 of the other portion.

The second bank 217 may be disposed on the first bank 316.

The organic layer 122 may be disposed on the second open area OA2 and the top surface and the side portion of the second bank 217.

The cathode 123 may be disposed on the organic layer 122.

The encapsulation layer ENCAP may be located above the above-described light emitting diode layer EDL.

The encapsulation layer ENCAP may have a single layer structure or a multi-layered structure. For example, the encapsulation layer ENCAP may be configured by the encapsulation unit 140 including a first inorganic insulating film, a foreign material compensation layer, and a second inorganic insulating film.

Even though it is not illustrated, in order to suppress the collapse of the encapsulation layer ENCAP, one or more dams may be disposed at an end portion of the inclined surface of the encapsulation layer ENCAP or in the vicinity thereof. One or more dams may be disposed in a boundary between the active area and the non-active area or in the vicinity of the boundary.

For example, the foreign material compensation layer including an organic material may be located only on an inner surface of the primary dam which is located in the innermost side. In this case, the foreign material compensation layer may not be provided above all the dams. In contrast, the foreign material compensation layer including an organic material may be disposed above at least the primary dam, between the primary dam and a secondary dam. For example, the foreign material compensation layer may be located to extend to the upper portion of the primary dam. Alternatively, for example, the foreign material compensation layer may be located to extend to the upper portion of the secondary dam by passing the upper portion of the primary dam.

The touch sensor layer TSL may be disposed above the above-described encapsulation layer ENCAP.

The touch sensor layer TSL may be configured by a touch buffer film 151, a bridge pattern 155, a touch insulating film 152, a touch electrode 156, and a touch planarization layer 157.

The black matrix 280 and the color filter layer 170 may be disposed above the touch sensor layer TSL.

Further, for example, the protection layer PAC may be disposed so as to cover the black matrix 280 and the color filter layer 170. The protection layer PAC may be configured by the organic insulating film of photo acryl (PAC).

Hereinafter, the lamination structure of the transmission area TA included in the first active area will be described.

Referring to FIG. 12, a part of the substrate SUB and various insulating layers 115a, 115b, 115c, 140, 151, 152, 157, and PAC disposed in the non-transmission area NTA of the first active area may also be disposed in the transmission area TA of the first active area in the same way.

For example, at least one of the first substrate 110a, the interlayer insulating layer 110c, the first planarization layer 115a, the second planarization layer 115b, the third planarization layer 115c, the encapsulation unit 140, the touch buffer film 151, the touch insulating film 152, the touch planarization layer 157, and the protection layer PAC which are disposed in the non-transmission area NTA of the first active area may also be disposed in the transmission area TA of the first active area in the same way.

However, in the non-transmission area NTA of the first active area, a material layer (for example, a metal material layer or a semiconductor layer) having an electric characteristic or an opaque characteristic, other than the insulating material, may not be disposed in the transmission area TA of the first active area.

For example, the metal material layers 135a, 135b, 131a, 131b, 132a, 132b, 133a, 133b, 125, 136a, and 136b and the semiconductor layers 134a and 134b related to the transistor may not be disposed in the transmission area TA. Further, the first bank 316, the second bank 217, and the light emitting diode 120 are not disposed in the transmission area TA. Further, the bridge pattern 155 and the touch electrode 156 included in the touch sensor layer TSL may not be disposed in the transmission area TA, but the present disclosure is not limited thereto.

In the meantime, according to one or more aspects of the present disclosure, a trench is formed between adjacent sub pixels to improve the current leakage through a common layer of the plurality of light emitting diode, which will be described in detail with reference to fourth and fifth example embodiments of the present disclosure.

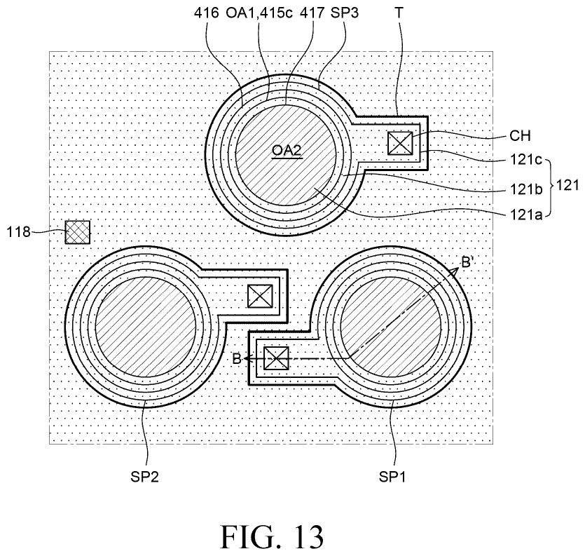

FIG. 13 is an example view illustrating a pixel structure of a display panel according to a fourth example embodiment of the present disclosure.

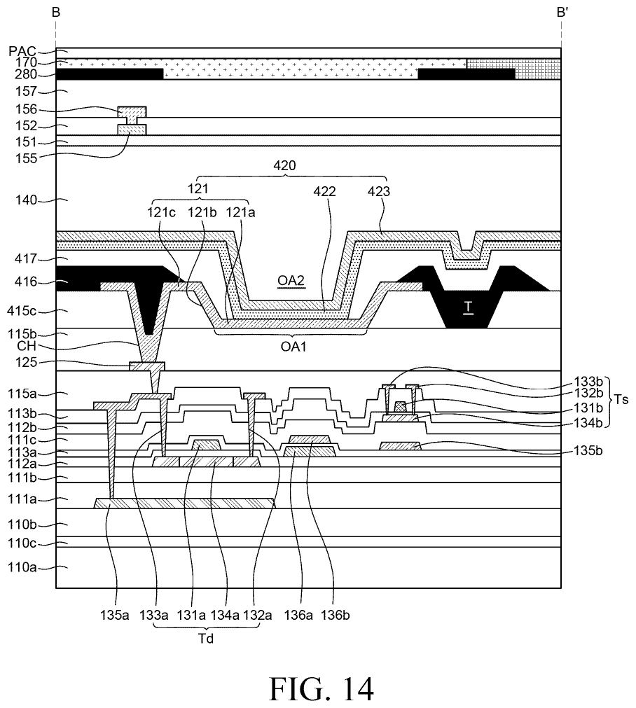

FIG. 14 is an example cross-sectional view taken along the line B-B′ of FIG. 13.

FIG. 13 illustrates a part of a display panel in which three sub pixels SP1, SP2, and SP3 are disposed as an example. Further, FIG. 13 illustrates a planar surface structure of a second bank 417 including a second open area OA2 which is a main emission area, an anode 121 with a side mirror structure, a first bank 416 disposed on a third area 121c of the anode 121, a third planarization layer 415c including a first open area OA1, a spacer 118, and a trench T disposed between the sub pixels SP1, SP2, and SP3.

FIG. 14 illustrates a part of a cross-section of one sub pixel of a display panel according to the fourth example embodiment of the present disclosure. For example, FIG. 14 illustrates a part of a cross-section obtained by cutting a center of the first sub pixel SP1 of FIG. 13 approximately in a left-right direction.

The fourth example embodiment of the present disclosure of FIGS. 13 and 14 is different from the second example embodiment of the present disclosure of FIGS. 6 and 7 described above in that a trench T is provided between adjacent sub pixels SP1, SP2, and SP3. However, the other configurations are substantially the same so that a redundant description will be omitted. Here, the descriptions of the same reference numerals may refer to the descriptions provided in connection with FIGS. 1 to 12.

Referring to FIGS. 13 and 14, as described above, a plurality of transistors, such as a driving transistor Td and a switching transistor Ts may be disposed above substrates 110a, 110b, and 110c.

The first planarization layer 115a, the second planarization layer 115b, and a third planarization layer 415c may be disposed above the driving transistor Td and the switching transistor Ts.

For example, the third planarization layer 415c may include a first open area OA1 obtained by removing (opening) a part of the third planarization layer 415c corresponding to a main emission area of the sub pixels SP1, SP2, and SP3, a reflective emission area, and a second non-emission area of the sub pixel.

Further, for example, the third planarization layer 415c may include a trench T obtained by removing (opening) a part of the third planarization layer 415c between adjacent sub pixels SP1, SP2, and SP3. At this time, in FIG. 14, it is illustrated that an entire thickness of the third planarization layer 415c is removed to form the trench T, but the present disclosure is not limited thereto and a part of the thickness of the third planarization layer 415c is removed to form the trench T. Further, in FIG. 14, it is illustrated that one trench T is formed in one sub pixel SP1, SP2, and SP3, but the present disclosure is not limited thereto and a plurality of trenches T may be formed.

In FIG. 13, it is illustrated that the trench T has a substantially circular annular shape without break along the outline of each sub pixel SP1, SP2, and SP3, but the present disclosure is not limited thereto and the trench may have a circular annular shape with a break. Further, when the sub pixel SP1, SP2, and SP3 have a polygonal shape, the trench T may have a polygonal annular shape without a break or a polygonal annular shape with break, along the outline of each sub pixel SP1, SP2, and SP3.

The trench T according to the fourth example embodiment of the present disclosure may be formed by etching the third planarization layer 415c by an additional mask process (or a photo process), but is not limited thereto.

The trench T as described above serves to improve a lateral leakage current generated in a multi-stack structure. That is, a current path of the organic layer 422 and the cathode 423 between the sub pixels SP1, SP2, and SP3 is increased due to the trench T according to the fourth example embodiment of the present disclosure. However, the present disclosure is not limited only to the multi-stack structure and may be effectively applied when a lateral leakage current is generated in the normal organic light emitting display device.

According to one or more aspects of the present disclosure, the path of the current path is increased to reduce the leakage current generated due to the use of the common layer due to the process characteristic of the organic light emitting display device, and mainly a leakage current generated when a current path is strongly formed in a low gray-scale area.

For example, the anode 121 may be disposed on a part of the top surface and the side portion of the third planarization layer 415c and a part of the top surface of the second planarization layer 115b.

The first bank 416 may be disposed on the third planarization layer 415c while covering a part of the anode 121.

The first bank 416 according to the fourth example embodiment of the present disclosure may cover a part of the third area 121c of the anode 121 including the contact hole CH and a part of the top surface of the third planarization layer 415c, and the other part of the top surface of the third planarization layer 415c including the trench T.

A part of the first bank 416 according to the fourth example embodiment of the present disclosure corresponding to the trench T may have a concave shape along the shape of the trench T.

The first bank 416 may be configured by a black based resin.

As described above, the first bank 416 of the fourth example embodiment of the present disclosure may be disposed on the third area 121c so as to cover a part of the third area 121c of the anode 121.

The second bank 417 may be disposed on the first bank 416.

The second bank 417 of the fourth example embodiment of the present disclosure may cover the first bank 416 and the other part of the second area 121b and the exposed third area 121c of the anode 121. Further, the second bank 417 of the fourth example embodiment of the present disclosure may cover a part of the edge of the first area 121a of the anode 121. Further, a part of the second bank 417 according to the fourth example embodiment of the present disclosure corresponding to the trench T may have a concave shape along the shape of the trench T.

The organic layer 422 may be disposed on the second open area OA2 and the top surface and the side portion of the second bank 417.

The cathode 423 may be disposed on the organic layer 422.

At this time, a part of the organic layer 422 and the cathode 423 of the fourth example embodiment of the present disclosure corresponding to the trench T may have a concave shape along the shape of the trench T so that the current path is increased to improve the lateral leakage current.

The encapsulation unit 140 may be disposed above the above-described light emitting diode 420.

A touch sensor layer configured by a touch buffer film 151, a bridge pattern 155, a touch insulating film 152, a touch electrode 156, and a touch planarization layer 157 may be disposed above the encapsulation unit 140.

The black matrix 280 and the color filter layer 170 may be disposed above the touch sensor layer.

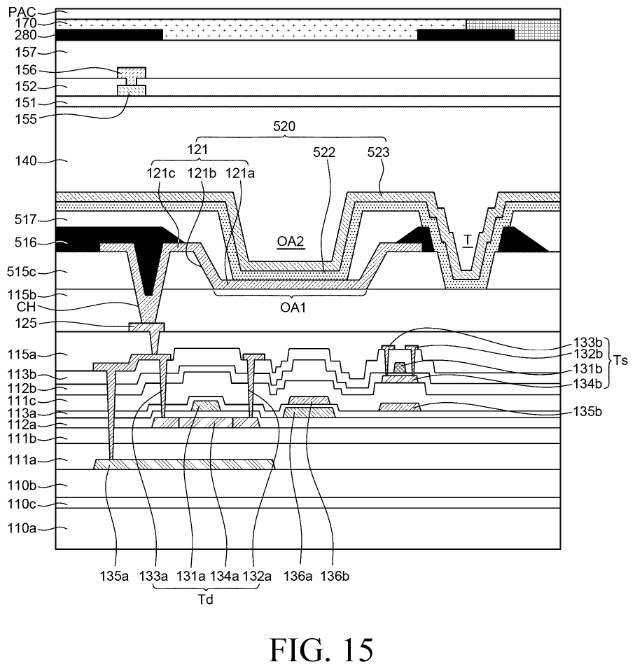

FIG. 15 is an example cross-sectional view illustrating a sub pixel structure of a fifth example embodiment of the present disclosure.

FIG. 15 illustrates a part of a cross-section of one sub pixel of a display panel according to the fifth example embodiment of the present disclosure.

The fifth example embodiment of the present disclosure of FIG. 15 is different from the second example embodiment of the present disclosure of FIGS. 6 and 7 described above in that a trench T is provided between adjacent sub pixels, but the other configurations are substantially the same so that a redundant description will be omitted. Here, the descriptions of the same reference numerals may refer to the descriptions provided in connection with FIGS. 1 to 14.

Referring to FIG. 15, as described above, a plurality of transistors, such as a driving transistor Td and a switching transistor Ts may be disposed above substrates 110a, 110b, and 110c.

The first planarization layer 115a, the second planarization layer 115b, and a third planarization layer 515c may be disposed above the driving transistor Td and the switching transistor Ts.

For example, the third planarization layer 515c may include first open area OA1 obtained by removing (opening) a part of the third planarization layer 515c corresponding to a main emission area, a reflective emission area, and a second non-emission area of the sub pixel.

Further, for example, the third planarization layer 515c may include a trench T obtained by removing (opening) a part of the third planarization layer 515c between adjacent sub pixels. At this time, in FIG. 15, it is illustrated that the trench T is formed by removing the entire thickness of the second bank 517, the first bank 516, and the third planarization layer 515c, but the present disclosure is not limited thereto. Therefore, the entire thickness of the second bank 517 and the first bank 516 and a part of the thickness of the third planarization layer 515c are removed to form the trench T. Further, in FIG. 15, it is illustrated that one trench T is formed in one sub pixel, but the present disclosure is not limited thereto and a plurality of trenches T may be formed.

The trench T according to the fifth example embodiment of the present disclosure may be formed by etching the second bank 517, the first bank 516, and the third planarization layer 515c using the existing photo process or laser melting, but is not limited thereto. In this case, the width and the depth of the trench T is increased as compared with the above-described fourth example embodiment so that the lateral leakage current may be more effectively improved.

As described above, the anode 121 may be disposed on a part of the top surface and the side portion of the third planarization layer 515c and a part of the top surface of the second planarization layer 115b.

The first bank 516 may be disposed on the third planarization layer 515c while covering a part of the anode 121.

The first bank 516 according to the fifth example embodiment of the present disclosure may cover a part of the third area 121c of the anode 121 including the contact hole CH and a part of the top surface of the third planarization layer 515c, and the other part of the top surface of the third planarization layer 515c excluding the trench T.

The first bank 516 may be configured by a black based resin.

As described above, the first bank 516 of the fifth example embodiment of the present disclosure may be disposed on the third area 121c so as to cover a part of the third area 121c of the anode 121.

The second bank 517 may be disposed on the first bank 516.

The second bank 517 of the fifth example embodiment of the present disclosure may cover the first bank 516 and the other part of the second area 121b and the exposed third area 121c of the anode 121. Further, the second bank 517 of the fifth example embodiment of the present disclosure may cover a part of the edge of the first area 121a of the anode 121. Further, the second bank 517 of the fifth example embodiment of the present disclosure may cover the first bank 516 excluding the trench T.

The organic layer 522 may be disposed on the second open area OA2 and the top surface and the side portion of the second bank 517. The organic layer 522 of the fifth example embodiment of the present disclosure may be disposed in the trench T.

The cathode 523 may be disposed on the organic layer 522. The cathode 523 of the fifth example embodiment of the present disclosure may be disposed in the trench T.

As described above, the organic layer 522 and the cathode 523 according to the fifth example embodiment of the present disclosure may be disposed in the trench T so that the current path is increased to improve the lateral leakage current.

The encapsulation unit 140 may be disposed above the above-described light emitting diode 520.

A touch sensor layer configured by a touch buffer film 151, a bridge pattern 155, a touch insulating film 152, a touch electrode 156, and a touch planarization layer 157 may be disposed above the encapsulation unit 140.

The black matrix 280 and the color filter layer 170 may be disposed above the touch sensor layer.

In the meantime, as described above, a distance between the boundary of the second area and the third area of the anode and the first bank is the same for all the sub pixels, but the present disclosure is not limited thereto and may vary for every sub pixel, which will be described in detail with reference to drawings.

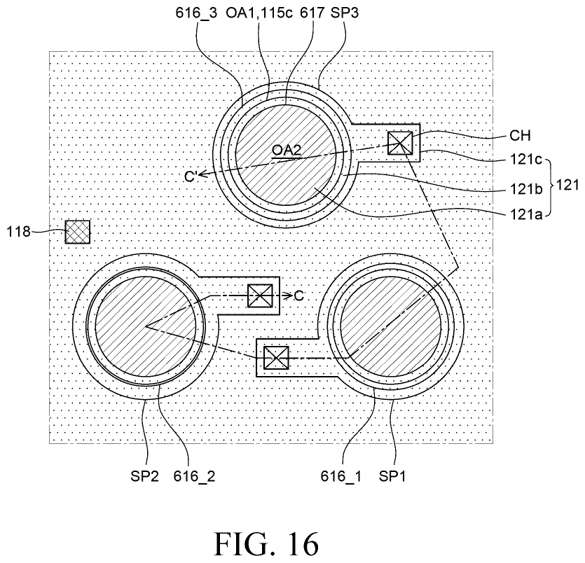

FIG. 16 is an example view illustrating a pixel structure of a display panel according to a sixth example embodiment of the present disclosure.

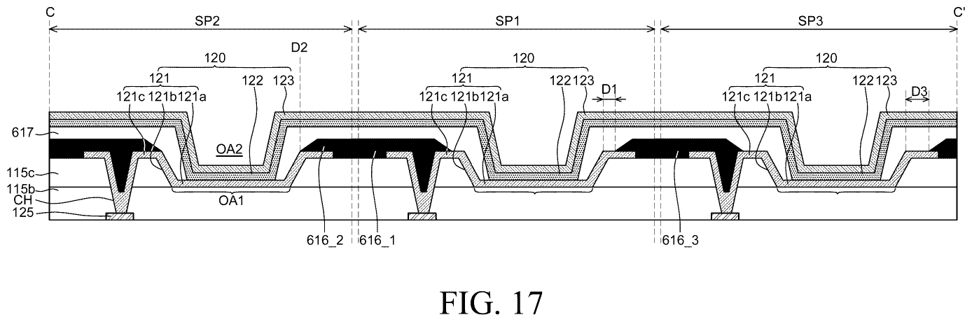

FIG. 17 is an example cross-sectional view taken along the line C-C′ of FIG. 16.

FIG. 16 illustrates a part of a display panel in which three sub pixels SP1, SP2, and SP3 are disposed as an example. Further, FIG. 16 illustrates a planar surface structure of a second bank 617 including a second open area OA2 which is a main emission area, an anode 121 with a side mirror structure, a first bank 616_1. 616_2, 616_3 disposed on a third area 121c of the anode 121, a third planarization layer 115c including a first open area OA1, and a spacer 118.

FIG. 17 illustrates a part of a cross-section of one pixel of a display panel according to the sixth example embodiment of the present disclosure. For example, FIG. 17 illustrates a part of cross-sections of the first sub pixel SP1, the second sub pixel SP2, and the third sub pixel SP3 of FIG. 16. In FIG. 17, for the sake of convenience, configurations above and below the light emitting diode 120 are not illustrated, but the present disclosure is not limited thereto.

The sixth example embodiment of the present disclosure of FIGS. 16 and 17 is different from the above-described second example embodiment of the present disclosure of FIGS. 6 and 7 in that distances D1, D2, and D3 of the first banks 616_1, 616_2, and 616_3 are different for individual sub pixels SP1, SP2, and SP3. The other configurations are substantially the same so that a redundant description will be omitted. Here, the descriptions of the same reference numerals may refer to the descriptions provided in connection with FIGS. 1 to 17.

Referring to FIGS. 16 and 17, as described above, the third planarization layer 115c may be disposed on the second planarization layer 115b.

For example, the anode 121 may be disposed on a part of the top surface and the side portion of the third planarization layer 115c and a part of the top surface of the second planarization layer 115b.

The first banks 616_1, 616_2, 616_3 may be disposed on the third planarization layer 115c while covering a part of the anode 121.

The first bank 616_1, 616_2, 616_3 according to the sixth example embodiment of the present disclosure may cover a part of the third area 121c of the anode 121 and a part of the top surface of the third planarization layer 115c, including the contact hole CH.

The first bank 616_1, 616_2, 616_3 according to the sixth example embodiment of the present disclosure may have different distances D1, D2, and D3 in the sub pixels SP1, SP2, and SP3. For example, the first bank 616_1, 616_2, 616_3 may include a first-first bank 616_1 disposed in the first sub pixel SP1, a second-first bank 616_2 disposed in the second sub pixel SP2, and a third-first bank 616_3 disposed in the third sub pixel SP3. Further, for example, the first-first bank 616_1 has a first distance D1, the second-first bank 616_2 has a second distance D2, and the third-first bank 616_3 has a third distance D3.

For example, in the first sub pixel SP1, the first distance D1 is between the boundary of the second area 121b and the third area 121c of the anode 121 and the first-first bank 616_1, in the second sub pixel SP2, the second distance D2 is between the boundary of the second area 121b and the third area 121c of the anode 121 and the second-first bank 616_2. Further, in the third sub pixel SP3, the third distance D3 is between the boundary of the second area 121b and the third area 121c of the anode 121 and the third-first bank 616_3. At this time, in FIG. 17, the second distance D2 is 0, the first distance D1 is larger than the second distance D2, and the third distance D3 is larger than the first distance D1, but the present disclosure is not limited thereto. For example, the first distance D1 is 0.5 μm, the second distance D2 is 0 μm, and the third distance D3 is 1.5 μm, but the present disclosure is not limited thereto. Further, according to one or more aspects of the present disclosure, the distance of any one sub pixel is different from the distance of another two sub pixels and the distance may vary for every sub pixel depending on the position of the display panel. For example, the distance of the sub pixel which is located at the edge of the display panel may be different from the distance of the sub pixel in the other position. Further, for example, the distance of the sub pixel which is located at the center of the display panel is different from the distance of the sub pixel in the other position. Further, when the present disclosure is applied to the above-described UDC model or UDIR mode, the distance of the sub pixel of the first active area may be different from the distance of the second active area.

The first banks 616_1, 616_2, and 616_3 may be configured by a black based resin.

As described above, the first banks 616_1, 616_2, and 616_3 of the sixth example embodiment of the present disclosure may be disposed on the third area 121c so as to cover a part of the third area 121c of the anode 121.

The second bank 617 may be disposed on the first banks 616_1, 616_2, and 616_3.

The second bank 617 of the sixth example embodiment of the present disclosure may cover the first banks 616_1, 616_2, and 616_3 and a part of the second area 121b and the exposed third area 121c of the anode 121. Referring to FIG. 17 as an example, the second bank 617 of the sixth example embodiment of the present disclosure covers the first-first bank 616_1 and the second area 121b and a part of the exposed third area 121c of the anode 121 in the first sub pixel SP1. Further, in the second sub pixel SP2, the second bank 617 covers the second-first bank 616_2 and the second area 121b of the anode 121 and in the third sub pixel SP3, covers the third-first bank 616_3, the second area 121b of the anode 121, and the other part of the exposed third area 121c, but the present disclosure is not limited thereto.

In the meantime, an encapsulation unit may be disposed above the light emitting diode 120.

Further, the touch sensor layer may be disposed above the encapsulation unit and the black matrix, and the color filter layer may be disposed above the touch sensor layer.

Various examples and aspects of the present disclosure are described below. These are provided as examples, and do not limit the scope of the present disclosure.

Referring back to FIGS. 4 and 5, the main emission area EA1 may correspond to an area in which a top surface of the anode 121 is exposed by the second bank 117. That is, the main emission area EA1 may be an area in which some of light emitted from the organic layer 122 is extracted to the outside of the display device via the organic layer 122 and the cathode 123.

The second non-emission area NEA2 may surround the main emission area EA1. The second non-emission area NEA2 may be an area in which some of light emitted from the organic layer 122 reaches the second bank 117 so that the light is not extracted, or is substantially not extracted, to the outside of the display device. The second non-emission area NEA2 may correspond to an area in which the anode 121 disposed on the top surface of the second planarization layer 115b is covered by the second bank 117.

The reflective emission area EA2 may surround the second non-emission area NEA2. The reflective emission area EA2 of a sub pixel may correspond to an area in which the anode 121 of the sub pixel is disposed on the inclined surfaces of the third planarization layer 115c at the sub pixel. That is, the reflective emission area EA2 may be an area in which some of light emitted from the organic layer 122 is reflected by the anode 121 disposed on the inclined surface (or the side portion having, e.g., a taper angle θ1) of the third planarization layer 115c.

The first non-emission area NEA1 may surround the reflective emission area EA2. The first non-emission area NEA1 may be an area in which components (e.g., transistor Td) for driving the light emitting diode 120 are disposed.

In one or more aspects, the foregoing descriptions with respect to FIGS. 4 and 5 apply to the elements with the same names and with the same or different reference numerals in connection with FIGS. 6, 7 and 12 to 17.

According to one or more aspects of the present disclosure, there is provided a display device. The display device includes: a main emission area EA1, a reflective emission area EA2, a first non-emission area NEA1, and a second non-emission area NEA2; a planarization layer disposed on a substrate and in the reflective emission area and the first non-emission area, without being disposed in the main emission area and the second non-emission area; an anode disposed on a portion of the planarization layer, disposed in the main emission area, the second non-emission area and the reflective emission area, and disposed in a part of the first non-emission area; a first bank disposed on a part of the anode and in a part of the first non-emission area, without being disposed in the main emission area, the second non-emission area and the reflective emission area; a second bank disposed on the first bank and in the reflective emission area, the first non-emission area, and the second non-emission area; an organic layer disposed on the anode; and a cathode disposed on the organic layer. The second non-emission area surrounds the main emission area, the reflective emission area surrounds the second non-emission area, and the first non-emission area surrounds the reflective emission area. The first bank comprises a black resin.

Various examples and aspects of the present disclosure are described below. These are provided as examples, and do not limit the scope of the present disclosure.

According to one or more aspects of the present disclosure, there is provided a display device. The display device includes a substrate, a plurality of sub pixels, a planarization layer disposed above the substrate and having a first open area, an anode disposed in the first open area and on a top surface and a side portion of the planarization layer, a first bank covering a part of the anode and comprising a black resin, a second bank covering the first bank and a side portion of the anode and having a second open area, an organic layer disposed on the anode exposed by the second open area and a cathode disposed on the organic layer.

The first open area may be wider than the second open area.

A side portion of the anode may correspond to a side portion of the planarization layer.

The display device may further comprise an encapsulation unit disposed above the cathode, a touch sensor layer disposed above the encapsulation unit and a black matrix and a color filter layer disposed above the touch sensor layer.

The black matrix may be spaced apart from an end of the first bank.

The anode, the organic layer, and the cathode may form a light emitting diode, the light emitting diode may define a main emission area, an area corresponding to the side portion of the anode may define a reflective emission area, and the reflective emission area may be formed around the main emission area.

The anode may include a first area disposed in the first open area, a second area extending from the first area to correspond to the side portion of the planarization layer and a third area extending from the second area and disposed on a top surface of the planarization layer.

A side portion of the first bank may have a taper angle smaller than a taper angle of the side portion of the planarization layer.

The second bank may cover the first bank and a part of the first area and the second area of the anode.

The first bank may cover all of the third area of the anode and the top surface of the planarization layer.

An end of the first bank may match an end of the third area.

The first bank may cover a part of the third area of the anode and a top surface of the planarization layer and may expose the other part of the third area of the anode.

The second bank may cover the first bank and a part of the first area, the second area, and the other exposed part of the third area of the anode.

An end of the first bank may be spaced apart from an end of the third area.

A distance between a boundary of the second area and the third area of the anode and the first bank may be from 0.5 μm to 1.5 μm.

The distance may be same for all of the plurality of sub pixels.

The distance may be different for each sub pixel.

The first bank may include a first-first bank disposed in a first sub pixel, a second-first bank disposed in a second sub pixel, and a third-first bank disposed in a third sub pixel.

The first-first bank may have a first distance, the second-first bank may have a second distance, and the third-first bank may have a third distance, and the first distance, the second distance, and the third distance may be different from each other.

An active area may be divided into a first active area and a second active area, and the first active area may include a transmission area and a non-transmission area.

The display device may further comprise a first pixel disposed in the non-transmission area of the first active area and a second pixel disposed in the second active area, the first pixel may be configured by a plurality of first sub pixels and the second pixel maty be configured by a plurality of second sub pixels.

The first pixel may have pixels per inch (PPI) smaller than PPI of the second pixel.

The display device may further comprise a light receiving device which overlaps the first active area.

The first bank may be disposed in the non-transmission area of the first active area and the second active area, but may not be disposed in the transmission area of the first active area.

A side portion of the first bank adjacent to the transmission area may have a taper angle different from a taper angle of another side portion of the first bank.

The planarization layer may include a trench formed by removing (opening) a part of the planarization layer between adjacent sub pixels.

The first bank may cover a part of the third area of the anode, a part of a top surface of the planarization layer, and the trench.

Parts of the first bank, the organic layer, and the cathode that correspond the trench may have a concave shape corresponding to a shape of the trench.

The first bank may cover a part of the third area of the anode, a part of a top surface of the planarization layer, and the other part of the top surface of the planarization layer excluding the trench and the second bank may cover the first bank and a part of the first area and the second area of the anode excluding the trench.

The organic layer and the cathode may be disposed in the trench.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a plurality of sub pixels;
a planarization layer disposed above the substrate and having a first open area;
an anode disposed in the first open area and on a top surface and a side portion of the planarization layer;
a first bank covering a part of the anode and comprising a black resin;
a second bank covering the first bank and a side portion of the anode and having a second open area;
an organic layer disposed on the anode exposed by the second open area; and
a cathode disposed on the organic layer.

2. The display device according to claim 1, wherein the first open area is wider than the second open area.

3. The display device according to claim 1, wherein the side portion of the anode corresponds to the side portion of the planarization layer.

4. The display device according to claim 1, further comprising:
an encapsulation unit disposed above the cathode;
a touch sensor layer disposed above the encapsulation unit; and
a black matrix and a color filter layer disposed above the touch sensor layer.

5. The display device according to claim 1, wherein the anode includes:
a first area disposed in the first open area;
a second area extending from the first area to correspond to the side portion of the planarization layer; and
a third area extending from the second area and disposed on the top surface of the planarization layer.

6. The display device according to claim 1, wherein a side portion of the first bank has a taper angle smaller than a taper angle of the side portion of the planarization layer.

7. The display device according to claim 5, wherein the second bank covers the first bank and a part of the first area and the second area of the anode.

8. The display device according to claim 5, wherein the first bank covers all of the third area of the anode and the top surface of the planarization layer.

9. The display device according to claim 8, wherein an end of the first bank matches an end of the third area.

10. The display device according to claim 1, wherein an active area is divided into a first active area and a second active area, and the first active area includes a transmission area and a non-transmission area.

11. The display device according to claim 10, further comprising:
a first pixel disposed in the non-transmission area of the first active area; and
a second pixel disposed in the second active area,
wherein the first pixel is configured by a plurality of first sub pixels and the second pixel is configured by a plurality of second sub pixels.

12. The display device according to claim 11, wherein the first pixel has pixels per inch (PPI) smaller than PPI of the second pixel.

13. The display device according to claim 10, further comprising:
a light receiving device which overlaps the first active area.

14. The display device according to claim 10, wherein the first bank is disposed in the non-transmission area of the first active area and the second active area, but is not disposed in the transmission area of the first active area.

15. The display device according to claim 10, wherein a side portion of the first bank adjacent to the transmission area has a taper angle different from a taper angle of another side portion of the first bank.

16. The display device according to claim 1, wherein the planarization layer includes a trench formed by opening a part of the planarization layer between adjacent sub pixels.

17. The display device according to claim 16, wherein the anode includes:
a first area disposed in the first open area;
a second area extending from the first area to correspond to the side portion of the planarization layer; and
a third area extending from the second area and disposed on the top surface of the planarization layer, and
wherein the first bank covers a part of the third area of the anode, a part of the top surface of the planarization layer, and the trench.

18. The display device according to claim 16, wherein parts of the first bank, the organic layer, and the cathode that correspond to the trench have a concave shape corresponding to a shape of the trench.

19. The display device according to claim 16, wherein the anode includes:
a first area disposed in the first open area;
a second area extending from the first area to correspond to the side portion of the planarization layer; and
a third area extending from the second area and disposed on the top surface of the planarization layer,
wherein the first bank covers a part of the third area of the anode, a part of the top surface of the planarization layer, and the other part of the top surface of the planarization layer excluding the trench, and
wherein the second bank covers the first bank and a part of the first area and the second area of the anode excluding the trench.

20. The display device according to claim 16, wherein the organic layer and the cathode are disposed in the trench.
